(19) United States
(12) Patent Application Publication
(10) Pub. No.: US 2025/0333845 A1
(43) Pub. Date: Oct. 30, 2025

(54) CONFORMAL COPPER DEPOSITION ON THIN LINER LAYER

(71) Applicant: Lam Research Corporation, Fremont, CA (US)

(72) Inventors: Weiping Jason ZHOU, Beaverton, OR (US); Lee J. BROGAN, Newberg, OR (US); Matthew Martin HUIE, Tigard, OR (US); Yi Hua LIU, Sherwood, OR (US); Artur KOLICS, Lake Oswego, OR (US); Jonathan David REID, Sherwood, OR (US)

(21) Appl. No.: 18/855,204

(22) PCT Filed: Apr. 6, 2023
(86) PCT No.: PCT/US2023/017687

§ 371 Date: Oct. 8, 2024

Related U.S. Application Data
(60) Provisional application No. 63/363,157, filed on Apr. 18, 2022.

(51) Int. Cl. C23C 18/16; C23C 18/18; C23C 18/40; C23C 28/02

(52) U.S. Cl. CPC C23C 18/1653; C23C 18/1827; C23C 18/40; C23C 28/021

(57) ABSTRACT

Various embodiments described herein relate to conformal deposition of a copper seed layer on a thin or ultrathin liner layer to enable bulk copper filling of a recessed feature. The copper seed layer may be continuous and thin, where a thickness can be equal to or less than about 30 Å. The liner layer may be very thin, where a thickness can be equal to or less than about 12 Å after deposition of the copper seed layer. In some implementations, the copper seed layer may be deposited directly on an ultrathin liner layer without etching the liner layer. In some implementations, the copper seed layer may be deposited on the liner layer while etching the liner layer to an ultrathin thickness. In some implementations, the copper seed layer is deposited by electroless plating.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### FIELD

Implementations herein relate to deposition of copper on liners and, more particularly, to conformal deposition of copper on liners for copper feature formation during semiconductor manufacturing.

### BACKGROUND

Semiconductor devices may be formed in a multi-level arrangement with electrically conductive structures in different levels insulated from each other by one or more intervening layers of dielectric material. The formation of electrically conductive structures in the semiconductor devices can be achieved using damascene or dual damascene processes. Trenches and/or holes are etched into the dielectric material and may be lined with one or more liner layers and barrier layers. Electrically conductive material may be deposited in the trenches and/or holes to form vias, contacts, or other interconnect features that extend through the dielectric material and provide electrical interconnection between the electrically conductive structures.

The background provided herein is for the purposes of generally presenting the context of the disclosure. Work of the presently named inventors, to the extent that it is described in this background, as well as aspects of the description that may not otherwise qualify as prior art at the time of filing, are neither expressly nor impliedly admitted as prior art against the present disclosure.

### SUMMARY

Provided herein is a method of depositing copper in one or more features of a substrate. The method includes receiving the substrate in a process chamber, where the substrate includes a dielectric layer having the one or more recesses formed therein, a barrier layer formed on the dielectric layer along sidewalls of the one or more recesses, and a liner layer formed on the barrier layer and along the sidewalls of the one or more recesses, where the liner layer includes a metal or metal alloy that is more noble than copper, and where the liner layer has a thickness equal to or less than about 12 Å. The method further includes conformally depositing a copper layer that is continuous over the liner layer, wherein the copper layer has a thickness equal to or less than about 30 Å.

In some implementations, conformally depositing the copper layer includes conformally depositing the copper layer by electroless deposition. In some implementations, the method further includes electrochemically filling the one or more recesses with copper over the copper layer to form a copper interconnect structure. In some implementations, the liner layer includes a catalytic metal or catalytic metal alloy for initiating electroless deposition of copper. In some implementations, the liner layer comprises ruthenium (Ru), platinum (Pt), palladium (Pd), rhodium (Rh), iridium (Ir), or alloys thereof. In some implementations, the liner layer has a thickness between about 2 Å and about 10 Å, and the copper layer has a thickness between about 5 Å and about 20 Å. In some implementations, the method further includes depositing the liner layer on the barrier layer by atomic layer deposition (ALD), chemical vapor deposition (CVD), physical vapor deposition (PVD), or ion implantation. In some implementations, the method further includes exposing the liner layer to a reducing atmosphere or reducing solution to treat the liner layer. In some implementations, an opening of each of the one or more recesses has a diameter equal to or less than about 10 nm.

Also provided herein is a method of depositing copper in one or more recesses of a substrate. The method includes receiving the substrate in a process chamber, where the substrate includes a dielectric layer having the one or more recesses formed therein, a barrier layer formed on the dielectric layer along sidewalls of the one or more recesses, and a liner layer formed on the barrier layer and along the sidewalls of the one or more recesses, where the liner layer includes a metal or metal alloy that is less noble than copper, and the liner layer has a thickness between about 5 Å and about 50 Å. The method further includes conformally depositing a copper layer over the liner layer, where the copper layer has a thickness equal to or less than about 30 Å, and etching the liner layer to a reduced thickness prior to or during deposition of the copper layer.

In some implementations, conformally depositing the copper layer includes conformally depositing the copper layer by electroless deposition. In some implementations, etching the liner layer to the reduced thickness occurs simultaneously with electroless deposition of the copper layer. In some implementations, the reduced thickness of the liner layer is less than about 5 Å after conformally depositing the copper layer. In some implementations, the method further includes electrochemically filling the one or more recesses with copper over the copper layer to form a copper interconnect structure. In some implementations, electrochemically filling the one or more recesses with copper includes one or both of electroless plating with copper and electroplating with copper. In some implementations, the liner layer includes a catalytic metal or catalytic metal alloy for initiating electroless deposition of copper. In some implementations, the liner layer includes cobalt (Co), nickel (Ni), zinc (Zn), tin (Sn), indium (In), germanium (Ge), rhenium (Re), tungsten (W), or alloys thereof. In some implementations, the copper layer has a thickness between about 10 Å and about 20 Å. In some implementations, the method further includes depositing the liner layer on the barrier layer by ALD, CVD, PVD, or ion implantation. In some implementations, the method further includes exposing the liner layer to a reducing atmosphere or reducing solution to treat the liner layer. In some implementations, an opening of each of the one or more recesses has a diameter equal to or less than about 10 nm.

Also provided herein is a method of depositing copper in one or more recesses of a substrate. The method includes receiving the substrate in a process chamber, where the substrate includes a dielectric layer having the one or more recesses formed therein, a barrier layer formed on the dielectric layer along sidewalls of the one or more recesses, and a liner layer formed on the barrier layer and along the sidewalls of the one or more recesses, where the liner layer includes a metal or metal alloy that is less noble than copper. The method further includes conformally depositing a copper layer over the liner layer by electroless deposition, and etching the liner layer to a reduced thickness prior to or during electroless deposition of the copper layer.

In some implementations, the method further includes etching the dielectric layer to form the one or more recesses in the dielectric layer, where an opening of each of the one or more recesses has a diameter equal to or less than about 10 nm, depositing the barrier layer along sidewalls and a bottom surface of the one or more recesses of the dielectric layer, and depositing the liner layer on the barrier layer by ALD, CVD, PVD, or ion implantation. In some implementations, the liner layer comprises Co, Ni, Zn, Sn, In, Ge, Re, W, or alloys thereof.

### BRIEF DESCRIPTION OF THE DRAWINGS

FIGS. 1A-1D show cross-sectional schematic illustrations of various processing stages including deposition of a barrier layer, a liner layer, and a copper seed layer according to some embodiments.

FIG. 2 shows a cross-sectional schematic illustration of a semiconductor substrate including a copper seed layer deposited by physical vapor deposition (PVD) on a liner layer.

FIG. 3 shows a cross-sectional schematic illustration of a semiconductor substrate including a copper seed layer deposited by electroplating on a thick liner layer.

FIG. 4A presents a flow diagram illustrating an example method of depositing a copper layer on a liner layer, where the liner layer is more noble than copper, according to some embodiments.

FIG. 4B presents a flow diagram illustrating an example method of depositing a copper seed layer by electroless deposition on an ultrathin liner layer, where the ultrathin liner layer is more noble than copper, according to some embodiments.

FIG. 5A presents a flow diagram illustrating an example method of depositing a copper layer on a liner layer, where the liner layer is less noble than copper, according to some embodiments.

FIG. 5B presents a flow diagram illustrating an example method of depositing a copper seed layer by electroless deposition on a thin liner layer, where the thin liner layer is less noble than copper, according to some embodiments.

FIGS. 6A-6B show cross-sectional schematic illustrations of processing stages for depositing a copper seed layer on an ultrathin liner layer that is more noble than copper according to some embodiments.

FIGS. 7A-7B show cross-sectional schematic illustrations of processing stages for depositing a copper seed layer on a thin liner layer that is less noble than copper according to some embodiments.

FIG. 8 shows a top view schematic illustration of an example process tool for electroless plating according to some embodiments.

FIG. 9 shows a schematic diagram of an example electroplating cell in which electroplating may occur according to some embodiments.

FIG. 10 shows a top view schematic diagram of an example process system for performing plating according to some embodiments.

FIG. 11 shows a top view schematic diagram of an alternative example process system for performing plating according to some embodiments.

### DETAILED DESCRIPTION

In the present disclosure, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 mm, or 300 mm, or 450 mm. The following detailed description assumes the present disclosure is implemented on a wafer. However, the present disclosure is not so limited. The work piece may be of various shapes, sizes, and materials. In addition to semiconductor wafers, other work pieces that may take advantage of the present disclosure include various articles such as printed circuit boards and the like.

### Introduction

Fabrication of electrically conductive structures in semiconductor devices often involves metal wiring that connects between semiconductor devices, other interconnecting wiring, and chip package connections. The electrically conductive structures may include line features (e.g., metal lines or metallization layers) that traverse a distance across a chip, and vertical interconnect features (e.g., vias) that connect the features in different levels. The interconnect features usually include copper (Cu), cobalt (Co), aluminum (Al), or tungsten (W) in both line and via structures, but may be fabricated with other conductive metals. The line features and interconnect features may be insulated by interlayer dielectrics (ILD) which are electrical insulators.

Integrated circuit (IC) fabrication methods commonly involve deposition of metals into recessed features formed in an ILD layer. The deposited metal provides the conductive paths which extend horizontally and/or vertically within the IC. Metal lines formed in adjacent ILD layers may be connected to each other by a series of vias or interconnect features. A stack containing multiple metal lines electrically connected to each other by one or more vias can be formed by a process known as dual damascene processing, but may also be formed using single damascene or subtractive processes. While the methods, apparatuses, and devices described below may be presented in the context of damascene processing, it will be understood that the methods, apparatuses, and devices of the present disclosure are not limited to only damascene processing and may be used in the context of other processing methods.

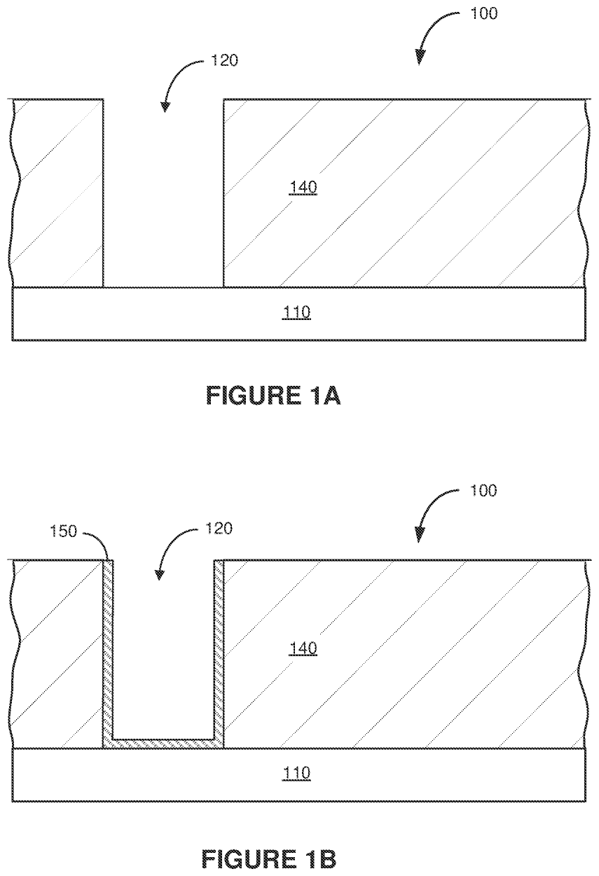

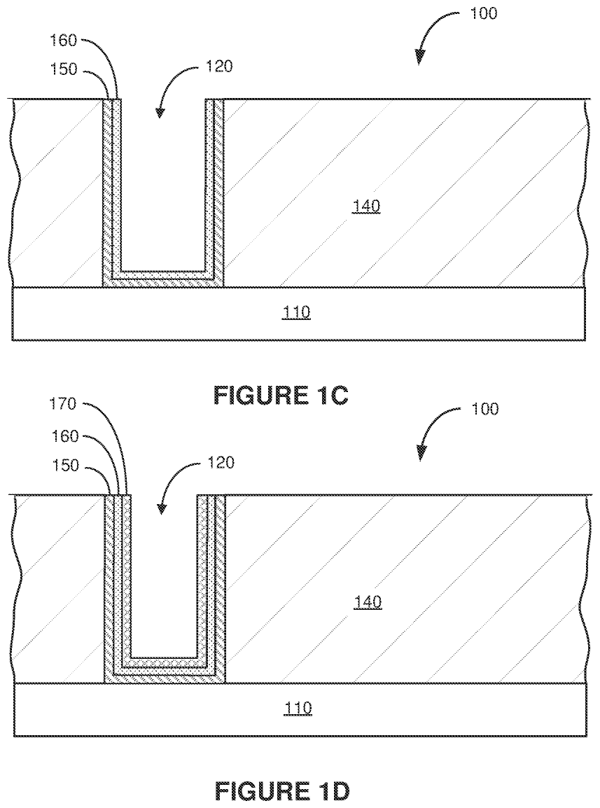

FIGS. 1A-1D show cross-sectional schematic illustrations of various processing stages including deposition of a barrier layer, a liner layer, and a copper seed layer according to some embodiments. In FIG. 1A, an example of a substrate 100 used for damascene processing is illustrated. In some implementations, the substrate 100 may include layers carrying active devices, such as transistors, or metallization layers containing copper or other type of metallization. The substrate 100 may be a semiconductor wafer, built on a semiconductor wafer, or part of a semiconductor wafer. The substrate 100 may include a dielectric layer 140 over a metallization layer 110. In some implementations, the dielectric layer 140 includes a fluorine-doped or carbon-doped silicon oxide or an organic-containing low-k material such as organosilicate glass (OSG). The dielectric layer 140 may be referred to as an interlayer dielectric (ILD), inter-metal dielectric, or insulating layer. In some implementations, the dielectric layer 140 includes multiple layers of dielectric materials. The metallization layer 110 may include an electrically conductive material such as copper. The metallization layer 110 may be referred to as a metal line, first metal line, or first metallization layer (e.g., M1). An etch stop layer (not shown) may be located between the metallization layer 110 and the dielectric layer 140. To form a conductive feature (e.g., via) through the dielectric layer 140, a recess 120 may be formed in the dielectric layer 140, which may be accomplished using a damascene process. The recess 120 may also be referred to as a recessed feature, trench, opening, or cavity. The recess 120 may be a high aspect ratio feature, where an aspect ratio of the recess 120 may be equal to or greater than about 5:1, equal to or greater than about 10:1, or equal to or greater than about 20:1. For example, the recess 120 may have an opening having a diameter equal to or less than about 10 nm. In some implementations, the recess 120 exposes a top surface of the metallization layer 110.

In FIG. 1B, a barrier layer 150 such as a diffusion barrier layer is formed in the recess 120. The barrier layer 150 may serve to protect the dielectric layer 140 and underlying active devices from diffusion of metal such as copper. Examples of barrier materials for the barrier layer 150 include but are not limited to titanium (Ti), tantalum (Ta), tantalum nitride (TaN), titanium nitride (TiN), titanium oxide (TiO₂), tungsten carbonitride (WCN), tungsten nitride (WN), molybdenum nitride (MoN), and fluorine-free tungsten (FFW). The barrier layer 150 may be deposited on the dielectric layer 140 such that the barrier layer 150 is formed along sidewalls and a bottom surface of the recess 120. The barrier layer 150 may be deposited in the recess 120 by any suitable deposition technique such as physical vapor deposition (PVD), chemical vapor deposition (CVD), atomic layer deposition (ALD), and plasma-enhanced chemical vapor deposition (PECVD). The barrier layer 150 may be composed of a material or combination of materials with properties and thickness sufficient to limit metal diffusion (e.g., copper movement) into surrounding materials (e.g., dielectric layer 140). In some embodiments, the barrier layer 150 has a thickness between about 1 Å and about 50 Å, between about 2 Å and about 30 Å, or between about 3 Å and about 10 Å.

In Figure 1C, a liner layer 160 is formed on the barrier layer 150. The liner layer 160 may serve to promote adhesion of copper or other metal along sidewalls and surfaces of the recess 120, as various materials may have difficulty wetting on the barrier layer 150. Additionally or alternatively, the liner layer 160 may serve as a catalytic film for nucleation of copper or other metal on sidewalls and surfaces of the recess 120. Examples of liner materials for the liner layer 160 may include ruthenium (Ru), platinum (Pt), palladium (Pd), rhodium (Rh), iridium (Ir), or alloys thereof. Such liner materials are more noble than copper. Alternatively, examples of liner materials for the liner layer 160 may include cobalt (Co), nickel (Ni), zinc (Zn), tin (Sn), indium (In), germanium (Ge), rhenium (Re), tungsten (W), or alloys thereof. Such liner materials are less noble than copper. The liner layer 160 may be deposited on the barrier layer 150 along sidewalls and the bottom surface of the recess 120. The liner layer 160 may be deposited in the recess 120 by any suitable deposition technique such as PVD, CVD, ALD, PECVD, and ion implantation. In some embodiments, the liner layer 160 is conformally deposited on the barrier layer 150 by ALD. In some embodiments, the liner layer 160 may be composed of a material that is catalytic to electroless plating. Typically, the liner layer 160 has a thickness of at least about 20 Å, or at least about 25 Å, such as between about 25 Å and about 100 Å or between about 30 Å and about 50 Å. Generally speaking, the liner layer 160 has to have sufficient thickness to avoid any plating issues related to a high sheet resistance associated with the combination of the barrier layer 150 and liner layer 160.

In FIG. 1D, a copper seed layer 170 is formed on the liner layer 160. The copper seed layer 170 may serve to promote nucleation of copper during copper electrodeposition for bulk feature filling of the recess 120. Because electroplating typically occurs on a conductive layer, the copper seed layer 170 is deposited over the liner layer 160 and the barrier layer 150. Current technology for metallization of integrated circuits include seeding the liner layer with copper via a PVD process. Alternatively, metallization of integrated circuits include seeding the liner layer with copper via a CVD process. Then filling the recess 120 can proceed using an electrodeposition process such as electroplating. The recess 120 may be electrochemically filled with a copper-containing metal on the copper seed layer 170. In some implementations, the filled recess may serve as a via or contact hole in a back-end-of-line (BEOL) semiconductor fabrication process. Alternatively, the filled recess may serve as a via or contact hole in a middle-of-line (MOL) semiconductor fabrication process

As discussed above, currently technology often deposits a copper seed layer over a barrier layer and/or liner layer by PVD. However, PVD copper seed is non-conformal. Because the PVD process is non-conformal, an overhang or thicker film is deposited more at the top of an opening of a recess (e.g., trench) than at the bottom of the recess. Typically, the PVD copper seed is reflowed or annealed so that the copper redistributes towards the bottom of the feature. The PVD copper seed may be reflowed to fill or at least partially fill the smaller or narrower features of a substrate. Thus, deposition of copper seed by PVD is limited because it is non-conformal that can lead to unwanted overhangs, and because the reflow step is hard to control, time-consuming, and potentially ineffective at smaller dimensions.

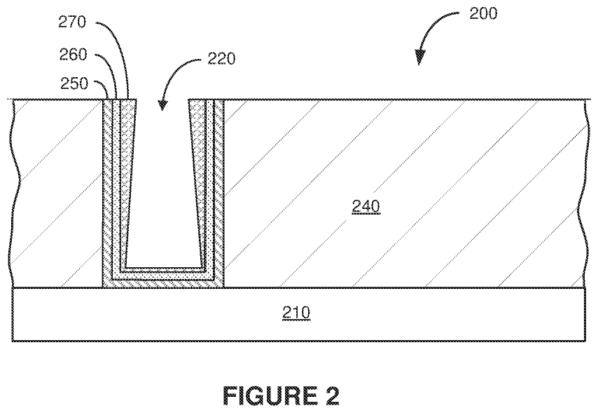

FIG. 2 shows a cross-sectional schematic illustration of a semiconductor substrate including a copper seed layer deposited by PVD on a liner layer. As shown in FIG. 2, a substrate 200 includes a dielectric layer 240 over a metallization layer 210. A recess 220 is etched through the dielectric layer 240 to expose a top surface of the metallization layer 210. A barrier layer 250 is deposited in the recess 220 along sidewalls and a bottom of the recess 220. A liner layer 260 is deposited over the barrier layer 250. A copper seed layer 270 is deposited by PVD over the liner layer 260, where the copper seed layer 270 is non-conformal and results in a thicker film near a top of the recess 220 than at the bottom of the recess 220. This non-conformality of deposition can be problematic in narrower features or high aspect ratio features, especially where the barrier layer 250 and/or liner layer 260 occupy a significant portion of a volume of the recess 220. Moreover, this non-conformality of deposition can result in pinch-offs and voids in metallization structures upon reflow.

In some cases, a copper seed layer may be deposited by electroplating over a barrier layer and/or liner layer. Or electroplating may proceed directly from the barrier/liner stack. In such cases, however, copper is plated on a liner layer having a high sheet resistance. For example, a thin ruthenium layer may have a sheet resistance of about 100 ohm/square to about 200 ohm/square. The sheet resistance of a layer decreases as its thickness increases. Accordingly, the liner layer has to be thick (e.g., greater than about 25 Å) in order to avoid plating issues related to the high sheet resistance of the barrier/liner stack. Increased liner thickness occupies more space in a recessed feature, causing the copper in the filled recess to occupy a smaller and smaller cross-sectional area especially as feature sizes shrink. Hence, having a thicker liner layer would significantly increase line and via resistance as well as introduce physical limitations as to what feature sizes can be employed.

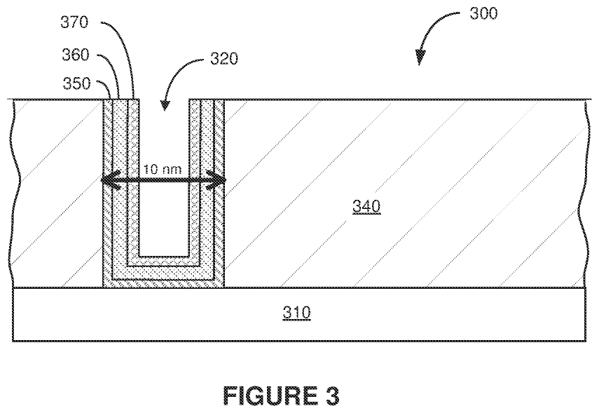

FIG. 3 shows a cross-sectional schematic illustration of a semiconductor substrate including a copper seed layer deposited by electroplating on a thick liner layer. As shown in FIG. 3, a substrate 300 includes a dielectric layer 340 over a metallization layer 310. A recess 320 is etched through the dielectric layer 340 to expose a top surface of the metallization layer 310. A barrier layer 350 is deposited in the recess 320 along sidewalls and a bottom of the recess 320. A liner layer 360 is deposited over the barrier layer 350. The liner layer 360 may have a thickness of at least about 25 Å, such as between about 25 Å and about 100 Å, or between about 30 Å and about 60 Å. The liner layer 360 has sufficient thickness to reduce sheet resistance so that electroplating can proceed on a thick liner layer. A copper seed layer 370 is plated on the liner layer 360. The copper seed layer 370 may be plated by exposing the substrate 300 to an electroplating solution and cathodically biasing the substrate 300 to plate the copper seed layer 370 on the liner layer 360.

Current copper BEOL interconnects will have very small trench openings. As shown in FIG. 3, the trench opening can be scaled down to 10 nm in diameter or less. This scaling generates significant challenges for effective electrochemical copper fill in narrow features. To enable large copper fill volume and reduced line and via resistance, the thicknesses of the barrier layer and/or liner layer need to be reduced. However, as shown in FIG. 3, where the liner layer 360 is very thick in the recess 320 that has an opening in which the diameter is 10 nm or less, this reduces the copper fill volume and increases the line and via resistance.

In some cases, a copper seed layer may be deposited by electroless plating over a liner layer. In these implementations, the liner layer is a catalytic film for electroless plating, since most materials of a barrier layer are not catalytic. By way of an example, a wet activation step exposes the barrier layer to a solution containing palladium ion or palladium colloid to produce palladium nuclei on the surface of the barrier layer. The presence of the palladium nuclei enables electroless plating However, nucleation density is often insufficient for achieving a continuous film of copper by electroless plating. In addition, the adhesion of copper deposited by electroless plating is usually inadequate when the nucleation density is not high.

### Deposition of Copper Seed Layer on Thin or Ultrathin Liner Layer

The present disclosure provides a copper layer deposited on a thin or ultrathin liner layer. The copper layer may serve as a copper seed layer to enable bulk copper electrofill to fill a recess. The copper seed layer may be continuous and thin, where a thickness can be equal to or less than about 30 Å or equal to or less than about 20 Å, so that the copper seed layer may be sufficiently thin to enable electrochemical copper fill. The liner layer may also be very thin, where a thickness can be equal to or less than about 12 Å or equal to or less than about 8 Å, so that the liner layer does not result in increased line and via resistance and so that electrochemical copper fill can occupy an increased volume. In some implementations, the copper layer is deposited by electroless plating. Where the liner layer is composed of a material more noble than copper, a continuous and thin copper layer can be deposited directly on an ultrathin liner layer without etching the liner layer. Where the liner layer is composed of a material less noble than copper, a continuous and thin copper layer can be deposited on a thin liner layer while etching the thin liner layer to a reduced thickness. In some such cases, etching the thin liner layer proceeds in a controlled manner simultaneous with an electroless copper plating process.

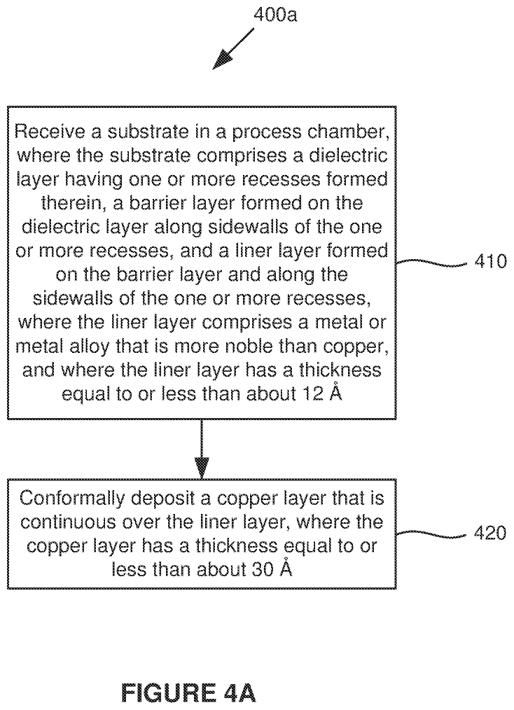

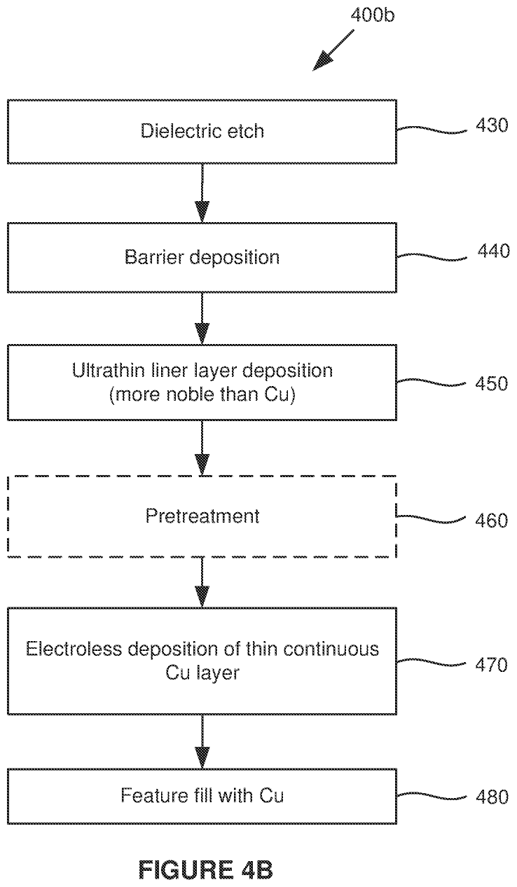

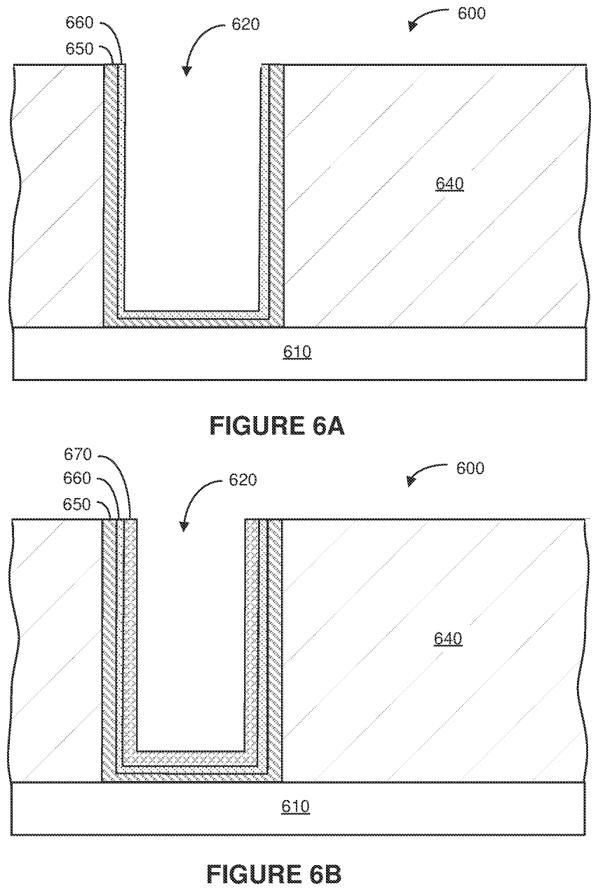

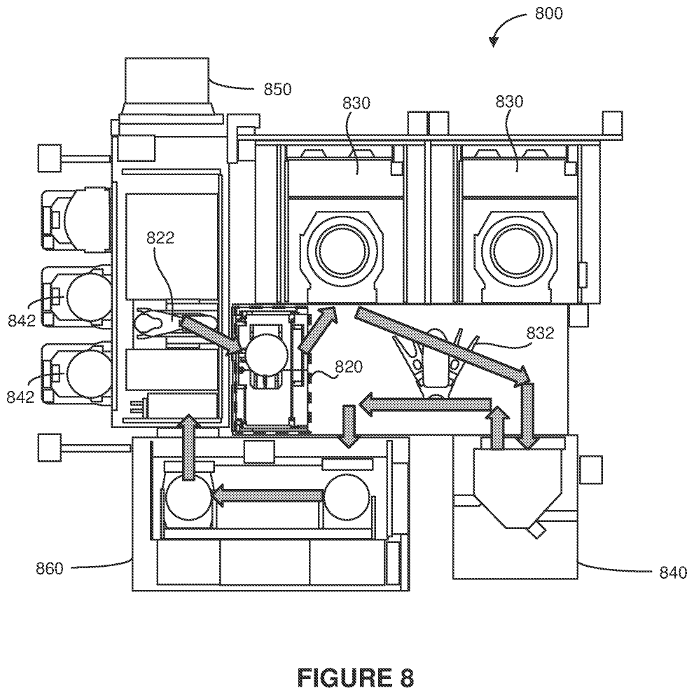

FIG. 4A presents a flow diagram illustrating an example method of depositing a copper layer on a liner layer, where the liner layer is more noble than copper, according to some embodiments. The operations in a process 400a may be performed in different orders and/or with different, fewer, or additional operations. Accompanying the description of the process 400a is a series of cross-sectional schematic illustrations of an example process of depositing a copper seed layer on an ultrathin liner layer in FIGS. 6A-6B. One or more operations of the process 400a may be performed using an apparatus as shown in FIGS. 8-11.

At block 410 of the process 400a, a substrate is received in a process chamber, where the substrate comprises a dielectric layer having one or more recessed formed therein. The substrate further comprises a barrier layer formed on the dielectric layer along sidewalls of the one or more recesses and a liner layer formed on the barrier layer and along the sidewalls of the one or more recesses. The liner layer comprises a metal or metal alloy that is more noble than copper, where the liner layer has a thickness equal to or less than about 12 Å.

The galvanic series determines the nobility of metals and metal alloys. When two metals are submerged in an electrolyte, the less noble metal will experience galvanic corrosion. Example metals that are more noble than copper include but are not limited to ruthenium (Ru), platinum (Pt), palladium (Pd), rhodium (Rh), iridium (Ir), and alloys thereof. Example metals that are less noble than copper include but are not limited to cobalt (Co), nickel (Ni), zinc (Zn), tin (Sn), indium (In), germanium (Ge), rhenium (Re), tungsten (W), and alloys thereof.

As used herein, the term “thin” associated with a copper layer in the present disclosure refers to a copper layer that is equal to or less than about 30 Å. As used herein, the term “thin” associated with a liner layer in the present disclosure refers to a liner layer that is equal to or less than about 15 Å. As used herein, the term “ultrathin” associated with a liner layer in the present disclosure refers to a liner layer that is equal to or less than about 12 Å.

The dielectric layer may be positioned over a metal layer of the substrate. The dielectric layer may be an interlayer dielectric or insulating layer. In some implementations, the dielectric layer includes a dielectric material or low-k dielectric material, where the dielectric material may include silicon oxide, fluorine-doped or carbon-doped silicon oxide, or an organic-containing low-k material such as OSG. The metal layer may be an underlayer conductor, a metal line, a metallization layer, or a patterned layer of metal for an interconnect. In some implementations, the metallic material of the metal layer may include copper, cobalt, aluminum, or tungsten.

One or more recesses are etched through the dielectric layer to expose the metal layer. The one or more recesses may be patterned using a standard lithography process. In some cases, the one or more recesses may constitute one or more trenches. In some implementations, the one or more recesses are formed according to a single damascene or dual damascene fabrication process. In some implementations, openings of the one or more recesses have a high aspect ratio. For example, aspect ratios of the one or more recesses may be equal to or greater than about 2:1, equal to or greater than about 5:1, equal to or greater than about 10:1, or equal to or greater than about 20:1. In some implementations, an average diameter of the openings of the one or more recesses may be equal to or less than about 15 nm, equal to or less than about 10 nm, or between about 3 nm and about 10 nm.

A barrier layer is deposited along sidewalls of the one or more recesses. The barrier layer may be deposited on exposed surfaces of the dielectric layer, including sidewalls of the one or more recesses. The barrier layer includes a material that limits diffusion of metal atoms into surrounding materials such as the dielectric layer. In some implementations, the barrier layer includes titanium, tantalum, tantalum nitride, titanium nitride, titanium oxide, tungsten carbonitride, tungsten nitride, molybdenum nitride, fluorine-free tungsten, or combinations thereof. In some implementations, the barrier layer is conformally deposited using a suitable deposition process such as ALD. In some implementations, the barrier layer has a thickness between about 1 Å and about 50 Å, between about 2 Å and about 30 Å, between about 2 Å and about 15 Å, or between about 3 Å and about 10 Å.

A liner layer is deposited on the barrier layer. The liner layer may be deposited on exposed surfaces of the barrier layer so that the liner layer is formed along sidewalls of the one or more recesses. The liner layer includes a material that promotes adhesion of copper on the barrier/liner stack and that additionally or alternatively serves as a catalytic film for electroless plating of copper. The liner layer includes a metal or metal alloy that is more noble than copper. The liner layer may include ruthenium, platinum, palladium, iridium, or combinations thereof. For instance, the liner layer may include ruthenium. In some implementations, the liner layer is composed of a catalytic metal or catalytic metal alloy that functions as an activation film for initiating electroless plating of copper. Accordingly, an activation step may be necessary to precede the electroless plating process. The liner layer may be deposited conformally using a suitable deposition technique such as ALD. Rather than wet activation on the barrier layer, deposition of the liner layer may provide dry activation on the barrier layer that precedes electroless plating. In some implementations, the liner layer is an ultrathin liner layer having a thickness equal to or less than about 10 Å, equal to or less than about 8 Å, equal to or less than about 5 Å, or between about 1 Å and about 5 Å. This allows for a monolayer or even sub-monolayer of catalytic film to be deposited on the barrier layer. Having an ultrathin liner layer reduces line and via resistance and also provides more volume for copper fill in the one or more recesses. In some implementations, the ultrathin liner layer may be continuous or may be discontinuous, as full coverage over the barrier layer is not necessarily required to achieve complete film closure with electroless plating of copper.

In some implementations, both the liner layer and the barrier layer are deposited using a vapor deposition process such as ALD. Thus, the barrier/liner stack may be deposited without introducing an air break between operations of deposition of the liner layer and deposition of the barrier layer. This prevents or limits unwanted oxides, impurities, and contaminants from forming on the substrate. Oxidation of the barrier layer makes subsequent deposition more difficult. Depositing the barrier/liner stack without introducing an air break also increases throughput. In some cases, deposition of the liner layer and the barrier layer may occur in the same processing chamber or tool.

In FIG. 6A, an example of a substrate 600 used for single damascene or dual damascene processing is illustrated. In some embodiments, the substrate 600 includes layers carrying active devices, such as transistors, or metallization layers containing copper or other types of metallization. The substrate 600 may include a dielectric layer 640 over a metallization layer 610. In some implementations, the dielectric layer 640 includes a fluorine-doped or carbon-doped silicon oxide or an organic-containing low-k material such as OSG. In some implementations, the dielectric layer 640 includes multiple layers of dielectric materials. The metallization layer 610 may include an electrically conductive material such as copper. The metallization layer 610 may be referred to as a metal line, first metal line, or first metallization layer (e.g., M1). An etch stop layer (not shown) may be located between the metallization layer 610 and the dielectric layer 640. To form a conductive feature (e.g., via) through the dielectric layer 640, a recess 620 may be formed in the dielectric layer 640. The recess 620 may be formed by a standard lithography process. In some implementations, the recess 620 is a trench. In some embodiments, the recess 620 has an aspect ratio equal to or greater than about 5:1, equal to or greater than about 10:1, or equal to or greater than about 20:1. In some embodiments, the recess 620 has an opening with a diameter equal to or less than about 10 nm. A barrier layer 650 is deposited in the recess 620 to at least line the sidewalls of the recess 620 of the dielectric layer 640. The barrier layer 650 may be deposited using any suitable deposition process such as PVD, CVD, ALD, or PECVD. The barrier layer may be composed of a material or combination of materials with properties and thickness sufficient to limit copper movement into the dielectric layer 640. In some embodiments, the thickness of the barrier layer 650 is between about 2 Å and about 20 Å. In some embodiments, the barrier layer 650 is composed of tantalum or tantalum nitride A liner layer 660 is deposited on the barrier layer 650 to further line the sidewalls of the recess 620 of the dielectric layer 640. The liner layer 660 may be deposited using any suitable deposition process such as CVD, ALD, PVD, or ion implantation. For example, the liner layer 660 and the barrier layer 650 may be both deposited using a vapor deposition process without introducing an air break in between deposition operations. The liner layer 660 may be composed of a catalytic metal or catalytic metal alloy that is more noble than copper. The liner layer 660 may be composed of a material that acts as an activation layer for electroless plating of copper. In some cases, the liner layer 660 includes ruthenium. In some embodiments, the thickness of the liner layer 660 is between about 1 Å and about 10 Å.

Returning to FIG. 4A, at block 420 of the process 400a, a copper layer is conformally deposited that is continuous over the liner layer, where the copper layer has a thickness equal to or less than about 30 Å. In some implementations, the copper layer is a seed layer for seeding the liner layer and providing a conductive surface on which copper fill can take place. In some implementations, the copper layer is conformally deposited by electroless plating. With electroless plating, the liner layer is contacted with a reducing chemical bath that initiates nucleation of copper on the liner layer. In some implementations, the copper layer is conformally deposited by ALD. In some other implementations, the copper layer is conformally deposited by CVD. In some implementations, deposition of the barrier layer, the liner layer, and the copper layer occur without introducing an air break in between operations, thereby preventing oxidation of the barrier layer and liner layer.

In some implementations, the copper layer has a thickness equal to or less than about 25 Å, equal to or less than about 20 Å, or between about 5 Å and about 20 Å. The copper layer may be a sufficient thickness to provide sufficient electrical conductivity for a subsequent electrodeposition (e.g., electroplating) process. In case of electroplating, the copper layer may have a minimum thickness of at least about 10 Å. In case of electroless plating, the copper layer may have a minimum thickness of at least about 4 Å. In some cases, the copper layer may be thin so that the thickness does not exceed 30 Å, does not exceed 25 Å, or does not exceed 20 Å. That way, bulk filling of copper can proceed from the copper layer in the one or more recesses in a void-free bottom-up fill manner.

In some implementations, the process 400a further includes electrochemically filling the one or more recesses with copper over the copper layer to form a copper interconnect structure. In some instances, the copper interconnect structure is a via providing electrical interconnection between metal lines or metallization layers. As used herein, electrochemically “filled” refers to partially filled or completely filled states of the one or more recesses. Electrochemical reactions at the surface the substrate occur, thereby causing bulk electroplating or bulk electroless plating of copper on the copper layer. The one or more recesses may be electrochemically filled by a bottom-up fill mechanism. In some implementations, an overburden may be deposited, where the overburden may include plated copper in field regions of the substrate. With electroplating of copper to fill the one or more recesses, the substrate may be exposed to an electroplating bath and the substrate is cathodically biased so that copper ions are electrochemically reduced to form copper on the copper layer. With electroless plating of copper to fill the one or more recesses, the substrate may be exposed to a reducing chemical bath so that a reducing agent catalytically oxidizes to transfer electrons to copper ions, thereby depositing copper over a catalytic layer. Where electroless plating is used for both copper layer deposition and electrochemical filling of the one or more recesses, the thickness of the copper layer does not matter as much.

In some implementations, the process 400a further includes treating the liner layer prior to conformally depositing the copper layer. In some implementations, treating the liner layer can include exposing the substrate to a reducing atmosphere or reducing solution to remove unwanted oxides and contaminants from the surface of the substrate. For example, the substrate can be exposed to hydrogen gas or hydrogen mixed with inert gases. Additionally or alternatively, the substrate can be exposed to hydrogen plasma or hydrogen-inert gas plasma. The plasma may be a remote plasma or direct plasma for reduction or metal oxide to metal. In some implementations, treating the liner layer can include exposing the substrate to a prewetting solution that contains one or more reducing agents dissolved in a solvent for improving nucleation and making the liner layer more catalytic.

In some implementations, the process 400a further includes cleaning the copper layer prior to electrochemically filling the one or more recesses. Cleaning the copper layer may include passivating the surface of the copper layer to minimize or otherwise reduce copper oxidation during transfer. Passivating the surface of the copper layer may provide an oxygen scavenger to remove oxygen from a solution during transfer. By way of an example, a continuous liquid layer may passivate the surface of the copper layer during transfer to an electroplating station, where the liquid layer may be a solution containing a passivator and/or oxygen scavenger, and having a pH between 4 and 13 or between 6 and 11. In some cases, the solution may include a solvent and optionally include a pH adjustor and a weakly adsorbing surfactant.

In FIG. 6B, a copper seed layer 670 is formed on the liner layer 660. The copper seed layer 670 may be conformally deposited on the liner layer 660. The copper seed layer 670 may be continuous over the liner layer 660. The copper seed layer 670 may be deposited directly over the liner layer 660 without etching the liner layer 660. As a result, the liner layer 660 maintains its thickness despite exposure to an electroless plating bath or deposition precursors. In some implementations, the copper seed layer 670 is conformally deposited on the liner layer 660 by electroless plating. In some other implementations, the copper seed layer 670 is conformally deposited on the liner layer 660 by ALD. In some implementations, a thickness of the copper seed layer 670 is between about 5 Å and about 20 Å.

FIG. 4B presents a flow diagram illustrating an example method of depositing a copper seed layer by electroless deposition on an ultrathin liner layer, where the ultrathin liner layer is more noble than copper, according to some embodiments. The operations in a process 400b may be performed in different orders and/or with different, fewer, or additional operations. One or more operations of the process 400b may be performed using an apparatus or apparatuses as shown in FIGS. 8-11.

At block 430 of the process 400b, a dielectric etch is performed on a substrate. The substrate may be a semiconductor wafer, built on a semiconductor wafer, or part of a semiconductor wafer. The substrate may include a dielectric layer over a metal layer. In some implementations, the dielectric layer includes a low-k dielectric material. The dielectric etch may be performed on the dielectric layer to form a trench in the dielectric layer. In some implementations, the dielectric etch is part of a single damascene or dual damascene process. The trench may have an aspect ratio equal to or greater than about 5:1, equal to or greater than about 10:1, or equal to or greater than about 20:1. In some implementations, a diameter of the opening of the trench may be between about 2 nm and about 20 nm, between about 3 nm and about 12 nm, such as about 10 nm.

At block 440 of the process 400b, a barrier layer is deposited in the trench of the dielectric layer. The barrier layer may line at least the sidewalls of the trench on exposed surfaces of the dielectric layer. The barrier layer may be deposited using any suitable deposition process such as PVD, CVD, ALD, or PECVD. The barrier layer may include a material having properties and sufficient thickness to limit copper diffusion into the dielectric layer. By way of an example, the barrier layer is composed of tantalum or tantalum nitride and has a thickness between about 2 Å and about 20 Å.

At block 450 of the process 400b, an ultrathin liner layer is deposited on the barrier layer. The ultrathin liner layer forms a barrier/liner stack in the trench of the dielectric layer. In some cases, the ultrathin liner layer is catalytic for electroless deposition of copper. The ultrathin liner layer has a thickness equal to or less than about 12 Å, or between about 1 Å and about 10 Å. The ultrathin liner layer is composed of a metal or metal alloy that is more noble than copper. For example, the ultrathin liner layer comprises ruthenium, platinum, palladium, rhodium, iridium, or alloys thereof. The ultrathin liner layer may be conformally deposited on the barrier layer using any suitable deposition process such as PVD, CVD, ALD, or ion implantation. By way of an example, the ultrathin liner layer is composed of ruthenium and has a thickness between about 1 Å and about 10 Å.

At block 460 of the process 400b, the ultrathin liner layer is optionally pre-treated prior to electroless deposition of copper on the ultrathin liner layer. Pre-treatment of the ultrathin liner layer may expose the ultrathin liner layer to a dry step, a wet step, or a combination of a wet and dry step. In some implementations, the dry step exposes the ultrathin liner layer to a reducing atmosphere for removal of oxides and/or impurities on the surface of the ultrathin liner layer. For example, the reducing atmosphere may include hydrogen or a combination of hydrogen with an inert gas in the absence of oxidizing agents using an anneal temperature between about 25° C. and about 400° C. In some implementations, the dry step exposes the ultrathin liner layer to a remote or direct plasma for removal of oxides and/or impurities on the surface of the ultrathin liner layer. For instance, the remote or direct plasma may include hydrogen plasma or hydrogen-inert gas plasma using an anneal temperature between about 25° C. and about 400° C. In some implementations, the wet step exposes the ultrathin liner layer to a solution containing one or more reducing agents dissolved in a solvent and applied to the surface of the ultrathin liner layer. The solution may serve as prewetting solution for nucleation enhancement of copper and/or removal of inhibitors. In some cases, the solution containing one or more reducing agents may be applied to the ultrathin liner layer at a temperature ranging from 10° C. to a boiling point of the solvent. Example reducing agents include but are not limited to: borohydride, hydrazine or alkyl hydrazines, amine boranes, aldehydes, D- or L-ascorbic acid, fructose, glucose, saccharose, metal ions such as vanadium (II), chromium (II), titanium (III), and iron (II), hypophosphite, gallic acid, and hydroquinone. The solution containing one or more reducing agents may further include a pH adjustor that can be a primary, secondary, tertiary, or quaternary alkyl or aryl amine, imine, alkanol amine, alkali or alkali earth metal hydroxide except lithium hydroxide (LiOH), sodium hydroxide (NaOH), and potassium hydroxide (KOH). Furthermore, the one or more reducing agents may be dissolved in a solvent, where the solvent includes water, simple alcohols (e.g., four carbon atoms or less) with a single or multiple hydroxides, apolar solvents such as toluene and hexane, ketones such as acetone and ethylbutylketone, ionic liquids, solvents with significant salt solubilizing capability such as dimethylsulfoxide, formamide, and acetonitrile, simple alkyl halides (e.g., four carbon atoms or less) such as carbon tetrachloride and chloroform, or mixtures thereof. In some implementations, the wet step exposes the ultrathin liner layer to a noble metal ion containing solution. As used herein, noble metal ions are metal ions in which the reduction potential are more positive than cobalt (II) ion. Such ions include but are not limited to ions of palladium, platinum, silver, copper, ruthenium, iridium, and rhodium. The noble metal ion containing solution may further include a solvent, a pH adjustor, and/or a complexing agent. In some implementations, the wet step exposes the ultrathin liner layer to a solvent. The solvent may include water, simple alcohols (e.g., four carbon atoms or less) with a single or multiple hydroxides, apolar solvents such as toluene and hexane, ketones such as acetone and ethylbutylketone, ionic liquids, solvents with significant salt solubilizing capability such as dimethylsulfoxide, formamide, and acetonitrile, simple alkyl halides (e.g., four carbon atoms or less) such as carbon tetrachloride and chloroform, or mixtures thereof. Any of the aforementioned wet steps may be applied at 10° C. up to a boiling point of the solvent. The wet steps may be applied with a surrounding ambient environment having a certain oxygen concentration that can be adjusted with a degasser in a chemical line and/or with inert gas in the ambient environment.

At block 470 of the process 400b, a thin continuous copper layer is deposited on the ultrathin liner layer by electroless deposition. In some cases, the thin continuous copper layer is a copper seed layer. In some implementations, the thin continuous copper layer is conformally deposited so that the thin continuous copper layer lines the ultrathin liner layer on sidewalls of the trench. Having the copper layer continuous protects the underlying liner from loss during subsequent operations. In some implementations, the thin continuous copper layer has a thickness equal to or less than about 25 Å, equal to or less than about 20 Å, or between about 5 Å and about 20 Å. Though the present disclosure describes electroless plating of copper, it will be understood that the present disclosure is not limited to electroless plating of pure copper but may include electroless plating of copper alloys. An alloying element or elements may include but are not limited to cobalt, nickel, zinc, tin, germanium, indium, gallium, and rhenium.

With electroless plating, also known as chemical or auto-catalytic plating, may be performed without use of external electrical power. Electroless plating may be employed to achieve conformal copper deposition to enable subsequent electroplating. Electroless plating takes place on a catalytic surface (i.e., the ultrathin liner layer). The substrate is contacted with an electroless plating bath to initiate electroless plating on the ultrathin liner layer. The electroless plating bath includes at least one of the following components: a source of copper ions, a reducing agent, a complexing agent, and a pH adjuster. The reducing agent may include, for example, an aldehyde moiety such as glyoxylic acid. The complexing agent can include ammonia, alkyl or arylamines, amino-carboxylates and its derivatives, carboxylic acids, and hydrocarboxylic acids. The pH adjuster can be primary, secondary, tertiary, or quaternary alkyl or aryl amines, imines, alkanol amines, alkali or alkali earth metal hydroxides except lithium hydroxide, sodium hydroxide, and potassium hydroxide. In some cases, the pH adjustor or the reducing agent can act as a complexing agent. Components of the electroless plating bath may be dissolved in a solvent such as water, alcohols, dimethylsulfoxide, acetonitrile, formamide, or ionic liquids. In some implementations, the electroless plating bath optionally includes one or more surfactants, stress-reducers, brighteners, suppressors, accelerators, oxygen scavengers, and/or one or more stabilizers. The electroless plating bath may be applied to initiate nucleation of copper on the ultrathin liner layer. The electroless plating bath at 10° C. up to a boiling point of the solvent. The electroless plating bath may be applied in an environment having a desired oxygen concentration to achieve an optimal film property. In some implementations, an oxygen concentration does not exceed 2 ppm in the electroless plating bath, where the oxygen level in the surrounding environment is equal to or less than about 0.5% by volume. The oxygen concentration may be controlled to control the plating reaction.

At block 480 of the process 400b, bulk copper is electroplated on the thin continuous copper layer to fill or at least partially fill features (e.g., trench). In some cases, electroplating of bulk copper may produce an overburden over the features. Bulk-layer electroplating may proceed in a void-free bottom-up fill mechanism. During bulk-layer electroplating, the substrate with the thin continuous copper layer may be immersed in an electroplating bath containing positive ions of copper and associated anions in an acidic solution. The bulk-layer electroplating process is able to fill the trench without voids. The filled trench may form at least a via for providing electrical interconnection between copper lines/wiring in the substrate.

Alternatively, bulk copper may be deposited by electroless plating on the copper layer to fill or at least partially fill features (e.g., trench). In such instances, a lower limit of the thickness of the copper layer does not matter and can be lower than 10 Å. In fact, the copper layer deposition and copper fill may be achieved in one step with electroless plating.

With electroplating, the substrate is contacted with an electroplating bath, which may also be referred to as an electrolyte, plating solution, plating bath, or aqueous electroplating solution. Electroplating may be performed with an external power source (e.g., DC power supply) to control electrical current flow to the substrate. The external power source may allow electroplating to proceed in a galvanostatic (controlled current) or potentiostatic (controlled potential) regime. The substrate may be cathodically biased to electrochemically fill the trench with copper. The electroplating bath may include a source of copper ions such as a copper salt. Examples of copper salts include copper sulfate (Cu(SO₄)) copper hydroxide (Cu(OH)₂), copper citrate (Cu₃(C₆H₅O₇)₂), copper pyrophosphate (Cu)P₂O₇), and copper oxalate (CuC₂O₄). In addition, the electroplating bath may include one or more complexing agents. Examples of complexing agents include but are not limited to ethylenediaminetetraacetic acid (EDTA), bipyridine, phenanthroline, ethylenediamine, oxalate, acetylacetonate, pyrophosphate, triethanolamine, dimercaptosuccinic acid, nitrilotriacetate, dimercaprol, and defuroxamine mesylate. In some implementations, the electroplating bath further includes an acid such as sulfuric acid for controlling a pH of the electroplating bath. In some implementations, the electroplating bath may further include balide ions, corrosion inhibiting agents, brighteners, levelers, accelerators, suppressors, and/or wetting agents.

In some embodiments, the substrate may undergo a transfer operation between electroless plating of the thin continuous copper layer and electroplating of bulk copper. During transfer, the thin continuous copper layer may be exposed to ambient conditions such that the thin continuous copper layer may oxidize. However, oxidation due to exposure to ambient conditions may be minimized by shortening the duration of transfer and/or controlling the atmosphere to be substantially devoid of oxygen. In some implementations, the substrate may undergo a dry or wet reducing treatment to reduce oxides and/or remove impurities after transfer. For example, the substrate may be exposed to a reducing atmosphere or plasma. In some implementations, the substrate may be rinsed and dried prior to bulk electroplating of copper.

In some implementations, after the bulk electroplating of copper at block 480, the process 400b may further include planarizing an overburden of copper. Planarization of copper may occur by chemical mechanical planarization (CMP) or other suitable technique known in the art. This may complete a damascene process for forming copper wiring and interconnects in a semiconductor device.

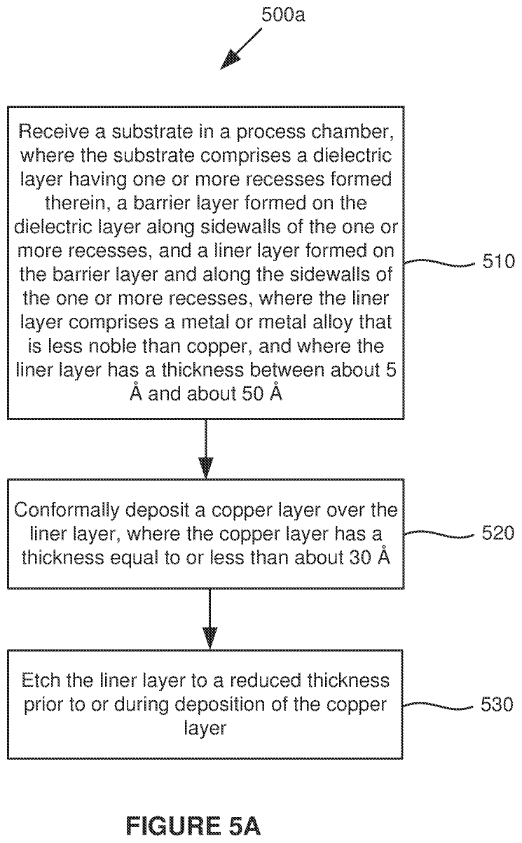

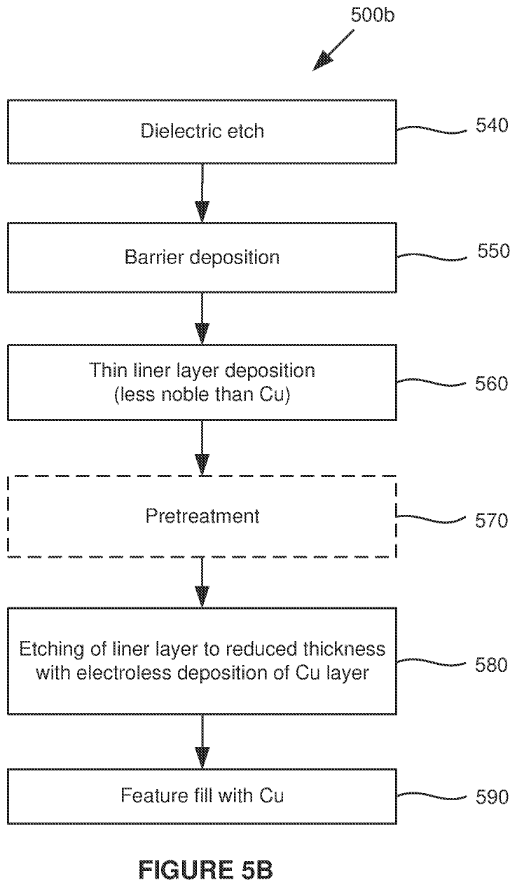

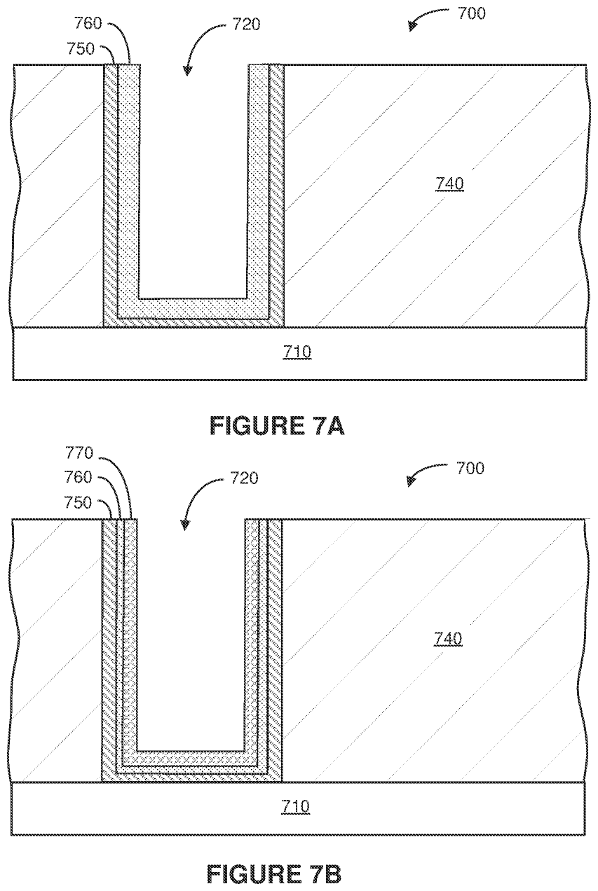

FIG. 5A presents a flow diagram illustrating an example method of depositing a copper layer on a liner layer, where the liner layer is less noble than copper, according to some embodiments. The operations in a process 500a may be performed in different orders and/or with different, fewer, or additional operations. Accompanying the description of the process 500a is a series of cross-sectional schematic illustrations of an example process of depositing a copper seed layer on a thin liner layer in FIGS. 7A-7B. One or more operations of the process 500a may be performed using an apparatus as shown in FIGS. 8-11.

At block 510 of the process 500a, a substrate is received in a process chamber, where the substrate comprises a dielectric layer having one or more recessed formed therein. The substrate further comprises a barrier layer formed on the dielectric layer along sidewalls of the one or more recesses and a liner layer formed on the barrier layer and along the sidewalls of the one or more recesses. The liner layer comprises a metal or metal alloy that is less noble than copper, where the liner layer has a thickness between about 5 Å and about 50 Å.

The dielectric layer may be positioned over a metal layer of the substrate. The dielectric layer may be an interlayer dielectric or insulating layer. In some implementations, the dielectric layer includes a dielectric material or low-k dielectric material, where the dielectric material may include silicon oxide, fluorine-doped or carbon-doped silicon oxide, or an organic-containing low-k material such as OSG. The metal layer may be an underlayer conductor, a metal line, a metallization layer, or a patterned layer of metal for an interconnect. In some implementations, the metallic material of the metal layer may include copper, cobalt, aluminum, or tungsten.

One or more recesses are etched through the dielectric layer to expose the metal layer. The one or more recesses may be patterned using a standard lithography process. In some cases, the one or more recesses may constitute one or more trenches. In some implementations, the one or more recesses are formed according to a single damascene or dual damascene fabrication process. In some implementations, openings of the one or more recesses have a high aspect ratio. For example, aspect ratios of the one or more recesses may be equal to or greater than about 2:1, equal to or greater than about 5:1, equal to or greater than about 10:1, or equal to or greater than about 20:1. In some implementations, an average diameter of the openings of the one or more recesses may be equal to or less than about 15 nm, equal to or less than about 10 nm, or between about 3 nm and about 10 nm.

A barrier layer is deposited along sidewalls of the one or more recesses. The barrier layer may be deposited on exposed surfaces of the dielectric layer, including sidewalls of the one or more recesses. The barrier layer includes a material that limits diffusion of metal atoms into surrounding materials such as the dielectric layer. In some implementations, the barrier layer includes titanium, tantalum, tantalum nitride, titanium nitride, titanium oxide, tungsten carbonitride, tungsten nitride, molybdenum nitride, fluorine-free tungsten, or combinations thereof. In some implementations, the barrier layer is conformally deposited using a suitable deposition process such as ALD. In some implementations, the barrier layer has a thickness between about 1 Å and about 50 Å, between about 2 Å and about 30 Å, between about 2 Å and about 15 Å, or between about 3 Å and about 10 Å.

A liner layer is deposited on the barrier layer. The liner layer may be deposited on exposed surfaces of the barrier layer so that the liner layer is formed along sidewalls of the one or more recesses. The liner layer includes a material that promotes adhesion of copper on the barrier/liner stack and that additionally or alternatively serves as a catalytic film for electroless plating of copper. The liner layer includes a metal or metal alloy that is less noble than copper. The liner layer may include cobalt, nickel, zinc, tin, indium, germanium, rhenium, tungsten, or combinations thereof. For instance, the liner layer may include cobalt. In some implementations, the liner layer is composed of a catalytic metal or catalytic metal alloy that functions as an activation film for initiating electroless plating of copper. Accordingly, an activation step may be necessary to precede the electroless plating process. The liner layer may be deposited conformally using a suitable deposition technique such as ALD. Rather than wet activation on the barrier layer, deposition of the liner layer may provide dry activation on the barrier layer that precedes electroless plating. In some implementations, the liner layer is a thin liner layer having a thickness equal to or less than about 50 Å, equal to or less than about 30 Å, equal to or less than about 25 Å, between about 5 Å and about 25 Å, or between about 10 Å and about 20 Å. The liner layer has sufficient thickness to allow subsequent etching. In some implementations, exposure to an electroless plating bath may etch the liner layer so that the liner layer is thinned to an ultrathin liner layer. Having an ultrathin liner layer reduces line and via resistance and also provides more volume for copper fill in the one or more recesses.

In some implementations, both the liner layer and the barrier layer are deposited using a vapor deposition process such as ALD. Thus, the barrier/liner stack may be deposited without introducing an air break between operations of deposition of the liner layer and deposition of the barrier layer. This prevents or limits unwanted oxides, impurities, and contaminants from forming on the substrate. Oxidation of the barrier layer makes subsequent deposition more difficult. Depositing the barrier/liner stack without introducing an air break also increases throughput. In some cases, deposition of the liner layer and the barrier layer may occur in the same processing chamber or tool.

In FIG. 7A, an example of a substrate 700 used for single damascene or dual damascene processing is illustrated. In some embodiments, the substrate 700 includes layers carrying active devices, such as transistors, or metallization layers containing copper or other types of metallization. The substrate 700 may include a dielectric layer 740 over a metallization layer 710. In some implementations, the dielectric layer 740 includes a fluorine-doped or carbon-doped silicon oxide or an organic-containing low-k material such as OSG. In some implementations, the dielectric layer 740 includes multiple layers of dielectric materials. The metallization layer 710 may include an electrically conductive material such as copper. The metallization layer 710 may be referred to as a metal line, first metal line, or first metallization layer (e.g., M1). An etch stop layer (not shown) may be located between the metallization layer 710 and the dielectric layer 740. To form a conductive feature (e.g., via) through the dielectric layer 740, a recess 720 may be formed in the dielectric layer 740 The recess 720 may be formed by a standard lithography process. In some implementations, the recess 720 is a trench. In some embodiments, the recess 720 has an aspect ratio equal to or greater than about 5:1, equal to or greater than about 10:1, or equal to or greater than about 20.1. In some embodiments, the recess 720 has an opening with a diameter equal to or less than about 10 nm. A barrier layer 750 is deposited in the recess 720 to at least line the sidewalls of the recess 720 of the dielectric layer 740. The barrier layer 750 may be deposited using any suitable deposition process such as PVD, CVD, ALD, or PECVD. The barrier layer may be composed of a material or combination of materials with properties and thickness sufficient to limit copper movement into the dielectric layer 740. In some embodiments, the thickness of the barrier layer 750 is between about 2 Å and about 20 Å. In some embodiments, the barrier layer 750 is composed of tantalum or tantalum nitride. A liner layer 760 is deposited on the barrier layer 750 to further line the sidewalls of the recess 720 of the dielectric layer 740. The liner layer 760 may be deposited using any suitable deposition process such as CVD, ALD, PVD, or ion implantation. For example, the liner layer 760 and the barrier layer 750 may be both deposited using a vapor deposition process without introducing an air break in between deposition operations. The liner layer 760 may be composed of a catalytic metal or catalytic metal alloy that is less noble than copper. The liner layer 760 may be composed of a material that acts as an activation layer for electroless plating of copper. In some cases, the liner layer 760 includes cobalt. In some embodiments, the thickness of the liner layer 760 is between about 5 Å and about 50 Å. The liner layer 760 in FIG. 7A may be thicker than the liner layer 660 in FIG. 6A.

Returning to FIG. 5A, at block 520 of the process 500a, a copper layer is conformally deposited over the liner layer, where the copper layer has a thickness equal to or less than about 30 Å. In some implementations, the copper layer is a seed layer for seeding the liner layer and providing a conductive surface on which copper fill can take place. In some implementations, the copper layer is conformally deposited by electroless plating. With electroless plating, the liner layer is contacted with a reducing chemical bath that initiates nucleation of copper on the liner layer. The reducing chemical bath may simultaneously etch the liner layer to a reduced thickness. In some implementations, the copper layer is conformally deposited by ALD. In some other implementations, the copper layer is conformally deposited by CVD. In some implementations, deposition of the barrier layer, the liner layer, and the copper layer occur without introducing an air break in between operations, thereby preventing oxidation of the barrier layer and liner layer. In some cases, the copper layer is continuous to protect the underlying liner layer from loss during subsequent operations

In some implementations, the copper layer has a thickness equal to or less than about 25 Å, equal to or less than about 20 Å, or between about 5 Å and about 20 Å. The copper layer may be a sufficient thickness to provide sufficient electrical conductivity for a subsequent electrodeposition (e.g., electroplating) process. In case of electroplating, the copper layer may have a minimum thickness of at least about 10 Å. In case of electroless plating, the copper layer may have a minimum thickness of at least about 4 Å. In some cases, the copper layer may be thin so that the thickness does not exceed 30 Å, does not exceed 25 Å, or does not exceed 20 Å. That way, bulk filling of copper can proceed from the copper layer in the one or more recesses in a void-free bottom-up fill manner.

At block 530 of the process 500a, the liner layer is etched to a reduced thickness prior to or during deposition of the copper layer. In cases where the copper layer is deposited by electroless deposition, the electroless plating bath etches the liner layer because the liner layer is composed of a metal or metal alloy that is less noble than copper. As a result, etching the liner layer and depositing the copper layer occur simultaneously. Put another way, the liner layer is etched during a period of time that the copper layer is being deposited by exposure to a plating solution. In cases where the copper layer is deposited by a vapor deposition technique such as ALD, the liner layer may be etched prior to deposition of the copper layer. For instance, the liner layer may be exposed to a dry or wet etchant for removing a portion of the liner layer. The liner layer may be etched sequentially rather than simultaneously with deposition of the copper layer. Where the liner layer is etched sequentially in some cases, an oxide layer of the liner layer may be etched before deposition of the copper layer takes place on the liner layer.

The liner layer is etched in a controlled manner so that a portion of the liner layer remains. The liner layer is etched to a reduced thickness so that a sufficient amount of catalytic film remains for depositing the copper layer and preventing barrier oxidation. Ordinarily, if a liner layer having a metal or metal alloy that is less noble then copper is too thin, this leaves the barrier layer vulnerable to oxidation during transfer and/or plating operations. Once the barrier layer is oxidized, it is often difficult to revert back to an oxide-free state. However, simultaneous liner etch and copper layer deposition provides protection to minimize or eliminate barrier oxidation, where the liner etch reduces a thickness of the liner layer without entirely removing the liner layer. The liner etch may stop when a continuous copper layer forms. By controlling conditions such as incoming liner layer thickness, queue time, and electroless plating parameters, the remaining liner layer thickness after the liner etch can be controlled. In some implementations, the liner layer is etched down to a reduced thickness equal to or less than about 10 Å, equal to or less than about 8 Å, equal to or less than about 5 Å, between about 3 Å and about 8 Å, or between about 3 Å and about 5 Å. In some implementations, the reduced thickness is at least about 40% less, at least about 50% less, at least about 60%, or at least about 70% less than the initially-deposited thickness of the liner layer. For example, if the initially-deposited thickness of the liner layer is between about 10 Å and about 20 Å, the reduced thickness of the liner layer after deposition of the copper layer may be between about 3 Å and about 5 Å.

In some implementations, the process 500a further includes electrochemically filling the one or more recesses with copper over the copper layer to form a copper interconnect structure. In some instances, the copper interconnect structure is a via providing electrical interconnection between metal lines or metallization layers. As used herein, electrochemically “filled” refers to partially filled or completely filled states of the one or more recesses. Electrochemical reactions at the surface the substrate occur, thereby causing bulk electroplating or bulk electroless plating of copper on the copper layer. The one or more recesses may be electrochemically filled by a bottom-up fill mechanism. In some implementations, an overburden may be deposited, where the overburden may include plated copper in field regions of the substrate. With electroplating of copper to fill the one or more recesses, the substrate may be exposed to an electroplating bath and the substrate is cathodically biased so that copper ions are electrochemically reduced to form copper on the copper layer. With electroless plating of copper to fill the one or more recesses, the substrate may be exposed to a reducing chemical bath so that a reducing agent catalytically oxidizes to transfer electrons to copper ions, thereby depositing copper over a catalytic layer. Where electroless plating is used for both copper layer deposition and electrochemical filling of the one or more recesses, the thickness of the copper layer does not matter as much.

In some implementations, the process 500a further includes treating the liner layer prior to conformally depositing the copper layer. In some implementations, treating the liner layer can include exposing the substrate to a reducing atmosphere or reducing solution to remove unwanted oxides and contaminants from the surface of the substrate. For example, the substrate can be exposed to hydrogen gas or hydrogen mixed with inert gases. Additionally or alternatively, the substrate can be exposed to hydrogen plasma or hydrogen-inert gas plasma The plasma may be a remote plasma or direct plasma for reduction or metal oxide to metal. In some implementations, treating the liner layer can include exposing the substrate to a prewetting solution that contains one or more reducing agents dissolved in a solvent for improving nucleation and making the liner layer more catalytic.

In some implementations, the process 500a further includes cleaning the copper layer prior to electrochemically filling the one or more recesses. Cleaning the copper layer may include passivating the surface of the copper layer to minimize or otherwise reduce copper oxidation during transfer. Passivating the surface of the copper layer may provide an oxygen scavenger to remove oxygen from a solution during transfer. By way of an example, a continuous liquid layer may passivate the surface of the copper layer during transfer to an electroplating station, where the liquid layer may be a solution containing a passivator and/or oxygen scavenger, and having a pH between 4 and 13 or between 6 and 11. In some cases, the solution may include a solvent and optionally include a pH adjustor and a weakly adsorbing surfactant.

In FIG. 7B, a copper seed layer 770 is formed on the liner layer 760. The copper seed layer 770 may be conformally deposited on the liner layer 760. The copper seed layer 770 may be continuous over the liner layer 760. The copper seed layer 770 may be deposited directly over the liner layer 760 while sequentially or simultaneously etching the liner layer 760. Where the copper seed layer 770 is deposited sequentially after partially etching the liner layer 760, this may occur where an oxide layer of the liner layer 760 is removed firstly and then the copper seed layer 770 is deposited on remaining portions of the liner layer 760. Where the copper seed layer 770 is deposited simultaneously while etching the liner layer 760, the liner layer 760 may be partially etched by an electroless plating bath and the copper seed layer 770 may be deposited using the same electroless plating bath. As a result, the liner layer 760 has a reduced thickness due to exposure to an electroless plating bath or etchant chemistry. The initial thickness of the liner layer 760 may be reduced from a thickness between about 5 Å and about 50 Å to a reduced thickness between about 3 Å and about 8 Å. In some implementations, the copper seed layer 770 is conformally deposited on the liner layer 760 by electroless plating. In some other implementations, the copper seed layer 770 is conformally deposited on the liner layer 760 by ALD. In some implementations, a thickness of the copper seed layer 770 is between about 5 Å and about 20 Å.

FIG. 5B presents a flow diagram illustrating an example method of depositing a copper seed layer by electroless deposition on a thin liner layer, where the thin liner layer is less noble than copper, according to some embodiments. The operations in a process 500b may be performed in different orders and/or with different, fewer, or additional operations. One or more operations of the process 500b may be performed using an apparatus or apparatuses as shown in FIGS. 8-11.

At block 540 of the process 500b, a dielectric etch is performed on a substrate. Aspects of the dielectric etch are described at block 430 of the process 400b in FIG. 4B.

At block 550 of the process 500b, a barrier layer is deposited in the trench of the dielectric layer. Aspects of the barrier layer deposition are described at block 440 of the process 400b in FIG. 4B.

At block 560 of the process 500b, a thin liner layer is deposited on the barrier layer. The thin liner layer forms a barrier/liner stack in the trench of the dielectric layer. In some cases, the thin liner layer is catalytic for electroless deposition of copper. The thin liner layer has a thickness equal to or less than about 100 Å, equal to or less than about 70 Å, equal to or less than about 50 Å, between about 5 Å and about 50 Å, or between about 10 Å and about 20 Å. The thin liner layer is composed of a metal or metal alloy that is less noble than copper. For example, the thin liner layer comprises cobalt, nickel, zinc, tin, indium, germanium, rhenium, tungsten, or alloys thereof. The thin liner layer may be conformally deposited on the barrier layer using any suitable deposition process such as PVD, CVD, ALD, or ion implantation. By way of an example, the thin liner layer is composed of cobalt and has a thickness between about 5 Å and about 50 Å.

At block 570 of the process 500b, the thin liner layer is optionally pre-treated prior to electroless deposition of copper on the ultrathin liner layer. Aspects of the pre-treatment of a liner layer are described at block 460 of the process 400b in FIG. 4B.

At block 580 of the process 500b, the thin liner layer is etched to a reduced thickness with electroless deposition of a copper layer. The copper layer may be a copper seed layer. Aspects of electroless deposition of a copper layer are described at block 470 of the process 400b in FIG. 4B.

The thin liner layer is simultaneously etched during electroless deposition of the copper layer. Because the thin liner layer comprises a metal or metal alloy that is less noble than copper, exposure to an electroless plating bath etches the thin liner layer. Thus, exposing the liner layer to an electroless plating bath both etches the thin liner layer and deposits the copper layer on top of the thin liner layer. The chemistry of electroless plating bath may be controlled to control etching of the thin liner layer. In some implementations, the oxygen concentration in the electroless plating bath may influence both the copper plating reaction and the liner etch reaction. The liner layer may be thinned down to a reduced thickness. In some implementations, the reduced thickness is between about 3 Å and about 8 Å or between about 3 Å and about 5 Å.

At block 590 of the process 500b, bulk copper is electroplated on the copper layer to fill or at least partially fill features (e.g., trench). Aspects of bulk-layer electroplating of copper are described at block 480 of the process 400b in FIG. 4B. Alternatively, bulk copper may be deposited by electroless plating on the copper layer to fill or at least partially fill features (e.g., trench). In such instances, a lower limit of the thickness of the copper layer does not matter and can be lower than 10 Å. In fact, the copper layer deposition and copper fill may be achieved in one step with electroless plating.

In some alternatives to the present disclosure, a copper layer may be deposited on an ultrathin liner layer by a vapor deposition technique such as CVD or ALD. In such instances, the ultrathin liner layer may include any suitable liner material regardless of whether the liner material is less noble or more noble than copper. For example, the ultrathin liner layer can include cobalt or ruthenium. The ultrathin liner layer may have a thickness equal to or less than about 12 Å or equal to or less than about 8 Å. The barrier layer, ultrathin liner layer, and copper layer may be deposited without introducing an air break in between operations. After deposition of the copper layer by CVD or ALD, bulk copper may fill one or more recesses in a substrate.

### Apparatus

The methods described herein may be performed by any suitable apparatus or set of apparatuses. A suitable apparatus includes hardware for accomplishing the process operations and a controller (e.g., system controller) having instructions for controlling process operations in accordance with the present implementations. For example, in some implementations, the hardware may include one or more process stations included in a process tool.

FIG. 8 shows a top view schematic illustration of an example process tool for electroless plating according to some embodiments. A process tool 800 may process one or more semiconductor substrates in a multi-chamber system or cluster tool that has the capability to sequentially process semiconductor substrates in a controlled manner. The process tool 800 may receive semiconductor substrates from a clean room for processing and return the semiconductor substrates to the clean room after processing. The process tool 800 may be used to deposit materials on the semiconductor substrates. For example, the process tool 800 may be used to deposit materials on the semiconductor substrates by electroplating or electroless plating. The process tool 800 may include multiple stations or chambers such as anneal stations, transfer stations, cleaning stations, metrology stations, brush stations, drying stations, pre-treatment stations, and deposition stations. Some may be wet processing stations and some may be dry processing stations. Semiconductor process tools typically include transfer robots to transfer semiconductor substrates between various chambers and stations. In FIG. 8, the process tool 800 includes a transfer station 820, one or more deposition stations 830, a cleaning station 840, and a drying station 860.

The process tool 800 includes one or more cassettes 842 for receiving semiconductor substrates. The one or more cassettes 842 may be pods or front opening unified pods (FOUPs) for receiving the semiconductor substrates that are to be processed in the process tool 800. A conveying robot 822 is configured to move along a semiconductor substrate and transfer the semiconductor substrate from the cassette 842 to the transfer station 820. In some implementations, the conveying robot 822 may have one or more arms. An arm may have an end effector for picking up the semiconductor substrate for transport.

The transfer station 820 may interface with multiple stations in the process tool 800. As shown in FIG. 8, the transfer station 820 may interface with the one or more deposition stations 830. The transfer station 820 may include at least a platform, pedestal, or other support(s) for supporting one or more semiconductor substrates. In some implementations, the transfer station 820 may be exposed to atmospheric conditions In some implementations, the transfer station 820 may be pumped down to sub-atmospheric pressures or vacuum pressures. In some implementations, the transfer station 820 may provide a flow of non-reactive gas such as argon (Ar) or nitrogen (N₂) to limit contamination/oxidation.

The transfer station 820 may be configured to transfer semiconductor substrates to the one or more deposition stations 830. In some implementations, the one or more deposition stations 830 may be electroless plating stations. However, it will be understood that the one or more deposition stations 830 may be any suitable deposition station for depositing materials, where the deposition station may be a PVD station, a CVD station, ALD station, or electroplating station. Where the one or more deposition stations 830 include a CVD station and/or ALD station, the one or more deposition stations 830 may be configured to deposit a barrier/liner stack in one or more recesses of a semiconductor substrate. In some cases, the one or more deposition stations 830 may be further configured to deposit a copper seed layer on the barrier/liner stack. In some embodiments, the one or more deposition stations 830 may perform electroplating or electroless plating operations on the semiconductor substrates, where the semiconductor substrates may be in a controlled environment and exposed to plating solution for selectively depositing metal (e.g., copper) on the surfaces of the semiconductor substrates.

After deposition, the semiconductor substrates may be transferred back to the transfer station 820 or moved via a handling robot 832 to the cleaning station 840. Though FIG. 8 depicts a cleaning station 840, it will be understood that the cleaning station 840 may be any post-deposition treatment station for treating semiconductor substrates after deposition. The cleaning station 840 may be configured to remove residual artifacts or contaminants from the surfaces of the semiconductor substrates. For instance, the cleaning station 840 may include a brush-box, fluid delivery nozzle, or other cleaning mechanism for cleaning the semiconductor substrates.

After cleaning, the semiconductor substrates may be returned to the transfer station 820 or moved via the handling robot 832 to a drying station 860. In some implementations, the drying station 860 is integrated with the cleaning station 840. In some implementations, the drying station 860 may expose the semiconductor substrates to drying gases. From the drying station 860, the semiconductor substrates may be returned to cassettes 842 via the conveying robot 822. As a result, semiconductor substrates may be returned having been cleaned and dried to a clean room after plating. The arrows in FIG. 8 illustrate a wafer path through the process tool 800.

A controller 850 is coupled to and controls the operations of one or more of the cassettes 842, the conveying robot 822, the transfer station 820, the one or more deposition stations 830, the handling robot 832, the cleaning station 840, and the drying station 860 of the process tool 800. The controller 850 controls some or all of the properties of the process tool 800. The controller 850 typically includes one or more memory devices and one or more processors. Aspects of the controller 850 are described in more detail below.

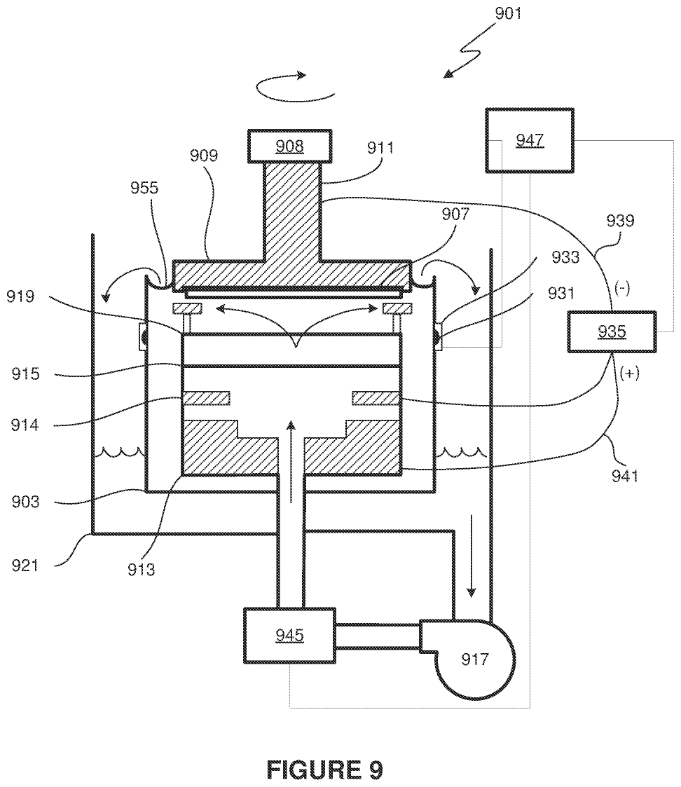

FIG. 9 shows a schematic diagram of an example electroplating cell in which electroplating may occur according to some embodiments. For example, bulk electroplating of copper may be performed using one or more electroplating cells depicted in FIG. 9. Only a single electroplating cell is shown in FIG. 9 to preserve clarity. Anodic and cathodic regions of the plating cell are sometimes separated by a membrane so that plating solutions of different composition may be used in each region. Plating solution in the cathodic region is called catholyte; and in the anodic region, anolyte. A number of engineering designs can be used in order to introduce anolyte and catholyte into the plating apparatus.

In FIG. 9, a diagrammatical cross-sectional view of an electroplating apparatus 901 in accordance with one implementation is shown. The electroplating apparatus 901 includes an electroplating chamber or plating bath 903 configured to hold an electroplating solution. The plating bath 903 contains the electroplating solution (having a composition as described herein), which is shown at a level 955. The catholyte portion of this vessel is adapted for receiving substrates in a catholyte. The electroplating apparatus 901 may further include a substrate holder or “clamshell” holding fixture 909 configured to hold a semiconductor substrate or wafer 907 in the electroplating solution. The wafer 907 is immersed into the electroplating solution and is held by, e.g., the “clamshell” holding fixture 909, mounted on a rotatable spindle 911, which allows rotation of “clamshell” holding fixture 909 together with the wafer 907. A general description of a clamshell-type plating apparatus having aspects suitable for use with this disclosure is described in detail in U.S. Pat. No. 6,156,167 issued to Patton et al., and U.S. Pat. No. 6,800,187 issued to Reid et al., which are incorporated herein by reference in their entireties and for all purposes.

An anode 913 is disposed below the wafer 907 within the plating bath 903 and is separated from the wafer region by a membrane 965, such as an ion selective membrane For example, Nafion™ cationic exchange membrane (CEM) may be used The region below the anodic membrane is often referred to as an “anode chamber.” The membrane 965 allows ionic communication between the anodic and cathodic regions of the plating cell, while preventing the particles generated at the anode from entering the proximity of the wafer 907 and contaminating it. The membrane 965 is also useful in redistributing current flow during the plating process and thereby improving the plating uniformity. Detailed descriptions of suitable anodic membranes are provided in U.S. Pat. Nos. 6,126,798 and 6,569,299 issued to Reid et al., both incorporated herein by reference in their entireties and for all purposes. Ion exchange membranes, such as cationic exchange membranes are especially suitable for these applications. These membranes are typically made of ionomeric materials, such as perfluorinated co-polymers containing sulfonic groups (e.g. Nafion™), sulfonated polyimides, and other materials known to those of skill in the art to be suitable for cation exchange. Selected examples of suitable Nafion™ membranes include N324 and N424 membranes available from Dupont de Nemours Co.

During plating, the ions from the electroplating solution are deposited on the wafer 907. The metal ions diffuse through the diffusion boundary layer and into the recessed feature (if present). A typical way to assist the diffusion is through convection flow of the electroplating solution provided by the pump 917. Additionally, a vibration agitation or sonic agitation member may be used as well as wafer rotation. For example, a vibration transducer 908 may be attached to the “clamshell” holding fixture 909.

The electroplating solution is continuously provided to plating bath 903 by the pump 917. Generally, the electroplating solution flows upwards through the membrane 965 and a diffuser plate 919 to the center of wafer 907 and then radially outward and across the wafer 907. The electroplating solution also may be provided into anodic region of the plating bath 903 from the side of the plating bath 903. The electroplating solution then overflows plating bath 903 to an overflow reservoir 921. The electroplating solution is then filtered (not shown) and returned to pump 917 completing the recirculation of the electroplating solution. In certain configurations of the plating cell, a distinct electrolyte is circulated through the portion of the plating cell in which the anode is contained while mixing with the main electroplating solution is prevented using sparingly permeable membranes or ion selective membranes.

A reference electrode 931 is located on the outside of the plating bath 903 in a separate chamber 933, which chamber is replenished by overflow from the main plating bath 903. Alternatively, in some implementations, the reference electrode 931 is positioned as close to the wafer surface as possible, and the reference electrode chamber is connected via a capillary tube or by another method, to the side of the wafer substrate or directly under the wafer substrate. In some implementations, the electroplating apparatus 901 further includes contact sense leads that connect to the wafer periphery and which are configured to sense the potential of the metal seed layer at the periphery of the wafer 907 but do not carry any current to the wafer 907.

A reference electrode 931 may be employed to facilitate electroplating at a controlled potential. The reference electrode 931 may be one of a variety of commonly used types such as mercury/mercury sulfate, silver chloride, saturated calomel, or copper metal. A contact sense lead in direct contact with the wafer 907 may be used in some implementations, in addition to the reference electrode 931, for more accurate potential measurement (not shown).

In some implementations, the electroplating apparatus 901 further includes a power supply 935. The power supply 935 can be used to control current flow to the wafer 907. The power supply 935 has a negative output lead 939 electrically connected to wafer 907 through one or more slip rings, brushes and contacts (not shown). The positive output lead 941 of power supply 935 is electrically connected to an anode 913 located in plating bath 903. The power supply 935, the reference electrode 931, and a contact sense lead (not shown) can be connected to a controller 947 (e.g., a system controller), which allows, among other functions, modulation of current and potential provided to the elements of electroplating cell. For example, the controller 947 may allow electroplating in potential-controlled and current-controlled regimes. The controller 947 may include program instructions specifying current and voltage levels that need to be applied to various elements of the plating cell, as well as times at which these levels need to be changed. When forward current is applied, the power supply 935 biases the wafer 907 to have a negative potential relative to anode 913. This causes an electrical current to flow from anode 913 to the wafer 907, and an electrochemical reduction reaction occurs on the wafer surface (the cathode), which results in the deposition of electrically conductive material (e.g., copper) on the surfaces of the wafer 907. An inert anode 914 may be installed below the wafer 907 within the plating bath 903 and separated from the wafer region by the membrane 965.

The electroplating apparatus 901 may also include a heater 945 for maintaining the temperature of the electroplating solution at a specific level. The electroplating solution may be used to transfer the heat to the other elements of the plating bath 903. For example, when a wafer 907 is loaded into the plating bath 903, the heater 945 and the pump 917 may be turned on to circulate the electroplating solution through the electroplating apparatus 901, until the temperature throughout the apparatus 901 becomes substantially uniform. In one implementation, the heater 945 is connected to the controller 947. The controller 947 may be connected to a thermocouple to receive feedback of the electroplating solution temperature within the electroplating apparatus 901 and determine the need for additional heating.

The controller 947 will typically include one or more memory devices and one or more processors. The processor may include a CPU or computer, analog and/or digital input/output connections, stepper motor controller boards, etc. In certain implementations, the controller 947 controls all of the activities of the electroplating apparatus 901 and/or of a pre-wetting chamber used to wet the surface of the substrate before electroplating begins. The controller 947 may also control all the activities of an apparatus used to deposit a conductive seed layer, as well as all of the activities involved in transferring the substrate between the relevant apparatuses.

For example, the controller 947 may include instructions for depositing a conductive seed layer, transferring the conductive seed layer to a pre-treatment chamber, performing pre-treatment, and electroplating in accordance with any method described above or in the appended claims. Non-transitory machine-readable media containing instructions for controlling process operations in accordance with the present disclosure may be coupled to the controller 947.

Typically there will be a user interface associated with controller 947. The user interface may include a display screen, graphical software displays of the apparatus and/or process conditions, and user input devices such as pointing devices, keyboards, touch screens, microphones, etc.

The computer program code for controlling electroplating processes can be written in any conventional computer readable programming language: for example, assembly language, C, C++, Pascal, Fortran or others. Compiled object code or script is executed by the processor to perform the tasks identified in the program.

In some implementations, the electroplating apparatus 901 includes the controller 947 configured with program instructions for performing the following operations: receiving a substrate in a process chamber, where the substrate includes a dielectric layer having one or more recesses formed therein, a barrier layer formed on the dielectric layer along sidewalls of the one or more recesses, a liner layer formed on the barrier layer and along the sidewalls of the one or more recesses, and conformally depositing a copper layer that is continuous over the liner layer. In some implementations, the controller 947 is further configured with program instructions for performing the following operations: etching the liner layer to a reduced thickness sequentially or simultaneously with conformally depositing the copper layer. In some implementations, the controller 947 is further configured with program instructions for performing the following operations: electroplating copper on the copper layer to fill the one or more recesses. In some implementations, the liner layer has a thickness equal to or less than about 12 Å. In some other implementations, the liner layer has a thickness between about 5 Å and about 50 Å. In some implementations, the copper layer has a thickness equal to or less than about 30 Å.

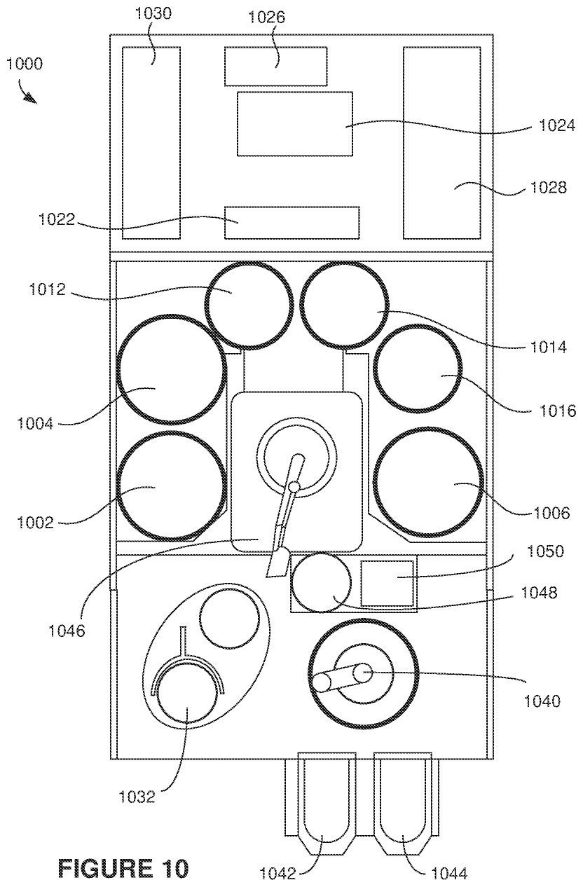

FIG. 10 shows a top view schematic diagram of an example process system for performing plating according to some embodiments. The electrodeposition apparatus 1000 can include three separate plating modules 1002, 1004, and 1006. Further, three separate modules 1012, 1014, and 1016 may be configured for various process operations. For example, in some embodiments, one or more of modules 1012, 1014, and 1016 may be a spin rinse drying (SRD) module. In these or other implementations, one or more of the modules 1012, 1014, and 1016 may be post-electrofill modules (PEMs). A module (e.g., one or more of modules 1012, 1014, and 1016) can be configured to perform a function, such as edge bevel removal, backside etching, and acid cleaning of substrates after they have been processed by one of the plating modules 1002, 1004, and 1006. Further, one or more of the modules 1012, 1014, and 1016 may be configured as a treatment chamber. The treatment chamber may be a remote plasma chamber, direct plasma chamber, or an anneal chamber. Alternatively, a treatment chamber may be included at another portion of the apparatus, or in a different apparatus.

The electrodeposition apparatus 1000 includes a central electrodeposition chamber 1024. The central electrodeposition chamber 1024 is a chamber that holds the chemical solution used as the electroplating solution or electroless plating solution in the plating modules 1002, 1004, and 1006. The electrodeposition apparatus 1000 also includes a dosing system 1026 that may store and deliver additives (e.g., wetting agents) for the electroplating solution or electroless plating solution. A chemical dilution module 1022 may store and mix chemicals to be used as an etchant. A filtration and pumping unit 1028 may filter the electroplating solution or electroless plating solution for the central electrodeposition chamber 1024 and pump it to the plating modules 1002, 1004, and 1006.

A controller 1030 (e.g., system controller) provides electronic and interface controls used to operate the electrodeposition apparatus 1000. Aspects of the controller 1030 are discussed above in the controller 947 of FIG. 9, and are described further herein. The controller 1030 (which may include one or more physical or logical controllers) controls some or all of the properties of the electrodeposition apparatus 1000. The controller 1030 typically includes one or more memory devices and one or more processors. The processor may include a central processing unit (CPU) or computer, analog and/or digital input/output connections, stepper motor controller boards, and other like components. Instructions for implementing appropriate control operations as described herein may be executed on the processor. These instructions may be stored on the memory devices associated with the controller 1030 or they may be provided over a network. In certain implementations, the controller 1030 executes system control software.

The system control software in the electrodeposition apparatus 1000 may include instructions for controlling the timing, mixture of electrolyte components (including the concentration of one or more electrolyte components), electrolyte gas concentrations, inlet pressure, plating cell pressure, plating cell temperature, substrate temperature, current and potential applied to the substrate and any other electrodes, substrate position, substrate rotation, and other parameters of a particular process performed by the electrodeposition apparatus 1000.

In one implementation of a multi-tool apparatus, the instructions can include inserting the substrate in a wafer holder, tilting the substrate, biasing the substrate during immersion, and electrodepositing an electrically conductive material (e.g., copper) in a recess of a substrate. The instructions may further include pre-treating the substrate, annealing the substrate after electroplating, and transferring the substrate as appropriate between relevant apparatus.

A hand-off tool 1040 may select a substrate from a substrate cassette such as the cassette 1042 or the cassette 1044. The cassettes 1042 or 1044 may be FOUPs. A FOUP is an enclosure designed to hold substrates securely and safely in a controlled environment and to allow the substrates to be removed for processing or measurement by tools equipped with appropriate load ports and robotic handling systems. The hand-off tool 1040 may hold the substrate using a vacuum attachment or some other attaching mechanism.

The hand-off tool 1040 may interface with a wafer handling station 1032, the cassettes 1042 or 1044, a transfer station 1050, or an aligner 1048. From the transfer station 1050, a hand-off tool 1046 may gain access to the substrate. The transfer station 1050 may be a slot or a position from and to which hand-off tools 1040 and 1046 may pass substrates without going through the aligner 1048. In some implementations, however, to ensure that a substrate is properly aligned on the hand-off tool 1046 for precision delivery to a plating module, the hand-off tool 1046 may align the substrate with an aligner 1048. The hand-off tool 1046 may also deliver a substrate to one of the plating modules 1002, 1004, or 1006, or to one of the separate modules 1012, 1014 and 1016 configured for various process operations.

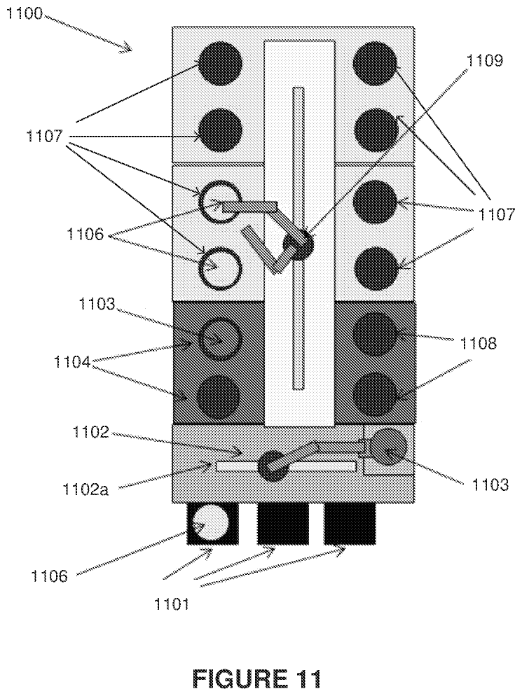

An apparatus configured to allow efficient cycling of substrates through sequential plating, rinsing, drying, and PEM process operations may be useful for implementations for use in a manufacturing environment. To accomplish this, the module 1012 can be configured as a spin rinse dryer and an edge bevel removal chamber. With such a module 1012, the substrate would only need to be transported between the plating module 1004 and the module 1012 for the metal plating and edge bevel removal (EBR) operations. One or more internal portions of the electrodeposition apparatus 1000 may be under sub-atmospheric conditions. For instance, in some implementations, the entire area enclosing the plating modules 1002, 1004 and 1006 and the modules 1012, 1014 and 1016 may be under vacuum. In other implementations, an area enclosing only the plating cells is under vacuum. In further implementations, the individual plating cells may be under vacuum. While electrolyte flow loops are not shown in FIG. 10 or 11, it is understood that the flow loops described herein may be implemented as part of (or in conjunction with) a multi-tool apparatus.

FIG. 11 shows a top view schematic diagram of an alternative example process system for performing plating according to some embodiments. In this implementation, the electrodeposition apparatus 1100 has a set of plating cells 1107, some or all containing a plating bath, in a paired or multiple “duet” configuration. In addition to plating per se, the electrodeposition apparatus 1100 may perform a variety of other plating related processes and sub-steps, such as spin-rinsing, spin-drying, metal and silicon wet etching, electroless deposition, pre-wetting and pre-chemical treating, reducing, annealing, photoresist stripping, and surface pre-activation, for example. The electrodeposition apparatus 1100 is shown schematically looking top down, and only a single level or “floor” is revealed in the figure, but it is to be readily understood by one having ordinary skill in the art that such an apparatus, e.g., the Sabre™ 3D tool of Lam Research Corporation of Fremont, CA can have two or more levels “stacked” on top of each other, some or all potentially having identical types of processing stations or different types of processing stations.

The substrates 1106 that are to be plated are generally fed to the electrodeposition apparatus 1100 through a front end loading FOUP 1101 and, in this example, are brought from the FOUP to the main substrate processing area of the electrodeposition apparatus 1100 via a front-end robot 1102 that can retract and move a substrate 1106 driven by a spindle 1103 in multiple dimensions from one station to another of the accessible stations-two front-end accessible stations 1104 and also two front-end accessible stations 1108 are shown in this example. The front-end accessible stations 1104 and 1108 may include, for example, pre-treatment stations, and spin rinse drying (SRD) stations. These front-end accessible stations 1104 and 1108 may also be removal stations as described herein. Lateral movement from side-to-side of the front-end robot 1102 is accomplished utilizing robot track 1102a. At least some of the substrates 1106 may be held by a cup/cone assembly (not shown) driven by a spindle 1103 connected to a motor (not shown), and the motor may be attached to a mounting bracket 1109. Also shown in this example are the four “duets” of plating cells 1107, for a total of eight plating cells 1107. The plating cells 1107 may be used for plating an electrically conductive material (e.g., copper) in a recess of a substrate. A controller (not shown) may be coupled to the electrodeposition apparatus 1100 to control some or all of the properties of the electrodeposition apparatus 1100. The controller may be programmed or otherwise configured to execute instructions according to processes described earlier herein.

In some implementations, a controller is part of a system, which may be part of the above-described examples Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some implementations, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition chamber or module, a chemical vapor deposition chamber or module, an atomic layer deposition chamber or module, an atomic layer etch chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The various hardware and method embodiments described above may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility.

Lithographic patterning of a film typically comprises some or all of the following steps, the steps enabled with a number of possible tools: (1) application of photoresist on a workpiece, e.g., a substrate having a silicon nitride film formed thereon, using a spin-on or spray-on tool; (2) curing of photoresist using a hot plate or furnace or other suitable curing tool; (3) exposing the photoresist to visible or UV or x-ray light with a tool such as a wafer stepper; (4) developing the resist so as to selectively remove resist and thereby pattern it using a tool such as a wet bench or a spray developer; (5) transferring the resist pattern into an underlying film or workpiece by using a dry or plasma-assisted etching tool; and (6) removing the resist using a tool such as an RF or microwave plasma resist stripper. In some embodiments, an ashable hard mask layer (such as an amorphous carbon layer) and another suitable hard mask (such as an antireflective layer) may be deposited prior to applying the photoresist.

### Conclusion

In the foregoing description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments are described in conjunction with the specific embodiments, it will be understood that it is not intended to limit the disclosed embodiments.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

The following claims are provided for further illustration of certain embodiments of the disclosure. The disclosure is not necessarily limited to these embodiments.

What is claimed is:

1. A method of depositing copper in one or more recesses of a substrate, the method comprising:
receiving the substrate in a process chamber, wherein the substrate comprises:
a dielectric layer having the one or more recesses formed therein;
a barrier layer formed on the dielectric layer along sidewalls of the one or more recesses; and
a liner layer formed on the barrier layer and along the sidewalls of the one or more recesses, wherein the liner layer comprises a metal or metal alloy that is more noble than copper, and wherein the liner layer has a thickness equal to or less than about 12 Å; and
conformally depositing a copper layer that is continuous over the liner layer, wherein the copper layer has a thickness equal to or less than about 30 Å.

2. The method of claim 1, wherein conformally depositing the copper layer comprises conformally depositing the copper layer by electroless deposition.

3. The method of claim 1, further comprising:
electrochemically filling the one or more recesses with copper over the copper layer to form a copper interconnect structure.

4. The method of claim 1, wherein the liner layer comprises a catalytic metal or catalytic metal alloy for initiating electroless deposition of copper.

5. The method of claim 4, wherein the liner layer comprises ruthenium (Ru), platinum (Pt), palladium (Pd), rhodium (Rh), iridium (Ir), or alloys thereof.

6. The method of claim 1, wherein the liner layer has a thickness between about 2 Å and about 10 Å, and wherein the copper layer has a thickness between about 5 Å and about 20 Å.

7. The method of claim 1, further comprising:
depositing the liner layer on the barrier layer by atomic layer deposition (ALD), chemical vapor deposition (CVD), physical vapor deposition (PVD), or ion implantation.

8. The method of claim 7, further comprising:
exposing the liner layer to a reducing atmosphere or reducing solution to treat the liner layer.

9. The method of claim 1, wherein an opening of each of the one or more recesses has a diameter equal to or less than about 10 nm.

10. A method of depositing copper in one or more recesses of a substrate, the method comprising:
receiving the substrate in a process chamber, wherein the substrate comprises:
a dielectric layer having the one or more recesses formed therein;
a barrier layer formed on the dielectric layer along sidewalls of the one or more recesses; and
a liner layer formed on the barrier layer and along the sidewalls of the one or more recesses, wherein the liner layer comprises a metal or metal alloy that is less noble than copper, and wherein the liner layer has a thickness between about 5 Å and about 50 Å;
conformally depositing a copper layer over the liner layer, wherein the copper layer has a thickness equal to or less than about 30 Å; and
etching the liner layer to a reduced thickness prior to or during deposition of the copper layer.

11. The method of claim 10, wherein conformally depositing the copper layer comprises conformally depositing the copper layer by electroless deposition.

12. The method of claim 11, wherein etching the liner layer to the reduced thickness occurs simultaneously with electroless deposition of the copper layer.

13. The method of claim 10, wherein the reduced thickness of the liner layer is less than about 5 Å after conformally depositing the copper layer.

14. The method of claim 10, further comprising:
electrochemically filling the one or more recesses with copper over the copper layer to form a copper interconnect structure.

15. The method of claim 14, wherein electrochemically filling the one or more recesses with copper comprises one or both of electroless plating with copper and electroplating with copper.

16. The method of claim 10, wherein the liner layer comprises a catalytic metal or catalytic metal alloy for initiating electroless deposition of copper.

17. The method of claim 16, wherein the liner layer comprises cobalt (Co), nickel (Ni), zinc (Zn), tin (Sn), indium (In), germanium (Ge), rhenium (Re), tungsten (W), or alloys thereof.

18. The method of claim 10, wherein the copper layer has a thickness between about 10 Å and about 20 Å.

19. The method of claim 10, further comprising:
depositing the liner layer on the barrier layer by ALD, CVD, PVD, or ion implantation.

20. The method of claim 19, further comprising:
exposing the liner layer to a reducing atmosphere or reducing solution to treat the liner layer.

21. The method of claim 10, wherein an opening of each of the one or more recesses has a diameter equal to or less than about 10 nm.

22. A method of depositing copper in one or more recesses of a substrate, the method comprising:
receiving the substrate in a process chamber, wherein the substrate comprises:
a dielectric layer having the one or more recesses formed therein;
a barrier layer formed on the dielectric layer along sidewalls of the one or more recesses; and
a liner layer formed on the barrier layer and along the sidewalls of the one or more recesses, wherein the liner layer comprises a metal or metal alloy that is less noble than copper;
conformally depositing a copper layer over the liner layer by electroless deposition; and
etching the liner layer to a reduced thickness prior to or during electroless deposition of the copper layer.

23. The method of claim 22, further comprising:
etching the dielectric layer to form the one or more recesses in the dielectric layer,
wherein an opening of each of the one or more recesses has a diameter equal to or less than about 10 nm; and
depositing the barrier layer along sidewalls and a bottom surface of the one or more recesses of the dielectric layer; and
depositing the liner layer on the barrier layer by ALD, CVD, PVD, or ion implantation.

24. The method of claim 22, wherein the liner layer comprises Co, Ni, Zn, Sn, In, Ge, Re, W, or alloys thereof.
